(19) United States
(12) Patent Application Publication
(10) Pub. No.: US 2024/0150569 A1
(43) Pub. Date: May 9, 2024

(54) 2K-System

(71) Applicant: Xetos AG, Hohenbrunn (DE)

(72) Inventor: Frank Knocke, Ebersberg (DE)

(21) Appl. No.: 18/276,755

(22) PCT Filed: Feb. 11, 2022
(86) PCT No.: PCT/EP2022/053408

§ 371 Date: Aug. 10, 2023

(30) Foreign Application Priority Data
Feb. 11, 2021 (EP) 21156623.7

(51) Int. Cl. C08L 35/02; C08F 22/20; C08K 5/46; C09B 21/00; C09K 11/02; C09K 11/06; G03H 1/02

(52) U.S. Cl. CPC C08L 35/02; C08F 22/20; C08K 5/46; C09B 21/00; C09K 11/02; C09K 11/06; G03H 1/02; C09K 2211/1018; G03H 2260/12

(57) ABSTRACT

The present invention relates to a two-component system for mixing photopolymerizable compositions and elements prepared therefrom, and to the use thereof. The photopolymerizable compositions are particularly suitable as recording materials for optical elements with refractive index modulation, in particular holograms.

### CROSS-REFERENCE TO RELATED APPLICATIONS

This application is the United States national phase of International Application No. PCT/EP2022/053408 filed Feb. 11, 2022, and claims priority to European Patent Application No. 21156623.7 filed Feb. 11, 2021, the disclosures of which are hereby incorporated by reference in their entireties.

### BACKGROUND OF THE INVENTION

### Field of the Invention

The present invention relates to a two-component system (kit-of-parts) and elements produced therefrom, as well as their use. The photopolymerizable compositions produced from the kit-of-parts are particularly suitable as recording materials for optical elements with refractive index modulation, in particular holograms.

### Description of Related Art

A variety of holograms such as reflection holograms, embossing holograms or transmission holograms or volume holograms are known.

A volume hologram is produced, for example, by bringing two light waves of the same wavelength, also called object and reference beam as well, to interference and exposing a holographic recording medium, usually a photographic film, to the resulting interference pattern, which is usually an intensity pattern. The holographic exposure process and the duplication of the hologram (replication) are technically complex optical processes that require special application knowledge.

The theory and methods for creating holograms are described extensively in the literature [Howard M. Smith, “Principles of Holography”, Wiley (1969)] [Fred Unterseher, et al. “Holography Handbook: Making Holograms the Easy Way”, Ross Books (1982)] [Graham Saxby, “Practical Holography”, Inst, of Physics Pub. (2004)].

Known recording materials with different property profiles and applications are: Silver halide emulsions, cured dichromate gelatin, ferroelectric crystals, photochromic and dichroid materials, and photopolymers [Howard M. Smith, “Principles of Holography”, Wiley (1969).]. For applications with high quantities, materials of interest are those that can be easily integrated into hologram production and duplication equipment and that allow for easy holographic exposure and development. Photopolymers are considered particularly preferred due to their high efficiency, ease of handling and good storage stability. The best known photopolymers are from DuPont, e.g. Omnidex HRF 600 [S. M. Schultz, et al. “Volume grating preferential-order focusing waveguide coupler,” Opt. Lett, vol. 24, pp. 1708-1710, December 1999]. Omnidex materials belong to the class of self-developing photo-polymer films based on radical polymerisation and monomer diffusion (see EP 0 324 480 A2).

Omnidex photopolymers have been further developed over the years, primarily with the aim to increase the refractive index contrast and to achieve a high diffraction efficiency in the film (see U.S. Pat. No. 4,942,112 A and DE 69032682 T2). Nevertheless, the application-relevant diffraction efficiencies of well over ⅔ are bought by a high proportion of thermoplastic binder.

For the film production, the binder for the coating must be liquid. For this purpose, a solvent is used, whereby evaporation of the solvent leads to a strong decrease in the layer thickness after coating. The wet layer to be applied is therefore much thicker than the resulting film layer, depending on the solvent content. The solvent content is usually about 80%. In order to achieve a layer of 20 μm that can be exposed by volume holography, a wet layer of 100 μm must be applied in this case. The required high thickness of the wet layer prevents or complicates the use of known printing processes, such as flexographic or gravure printing. In screen printing, the use of fast-drying solvents can cause the mesh to stick together.

Moreover, the film can only be further processed or wound up when all the solvent has evaporated. In production, therefore, in a long drying line a health- and environment-friendly extraction system has to be established, as well as a dust- and explosion-proof environment. This effort means that film production and holographic exposure usually take place at separate locations and times.

In the case of binder-containing materials, thermal post-treatment (“annealing”) of the exposed and UV-fixed photopolymer is also necessary to achieve the maximum refractive index contrast (see DE 68905610 T2). Annealing is an additional time-consuming processing step that slows down, complicates and increases the cost of hologram production in addition to the time-consuming film production, and also limits the choice of substrate materials to those that are not temperature-sensitive.

Other photopolymer materials for volume holography have been produced by Polaroid (see U.S. Pat. No. 5,759,721 A, Fuji Photo Film (see EP 1 510 862 A2), Konica Minolta Medical & Graphic (see US 200505891 A1), Dai Nippon Printing (see EP 123151 A1), Nippon Paint (see EP 0 211 615 A2), Nissan Chemical Industries (see US 20050068594 A1), Bayer (see WO 2010091795 A1), Xetos (see WO 2003036389 A1) and InPhase Technologies (see US 2002142227 A1). The prior art features photopolymers that differ from Omnidex in their holographic properties or processing. Technical progress is documented by reduced oxygen sensitivity, reduced material shrinkage during exposure, adjusted spectral sensitivity (sensitivity), solvent-free film production, higher diffraction efficiency without annealing and/or better temperature and storage stability.

EP 3 313 827 B1 relates to aromatic 4,6-bis-trichloromethyl-s-triazin-2-yl compounds of formula (I). Other objects of the invention are a photopolymer formulation containing a photopolymerizable component and at least one aromatic 4,6-bis-trichloromethyl-s-triazin-2-yl compound of formula (I) and a photopolymer comprising matrix polymers, a writing monomer, a photoinitiator and at least one aromatic 4,6-bis-trichloromethyl-s-triazin-2-yl compound of formula (I), a holographic medium containing the corresponding photo-polymer according to the invention, a hologram containing a holographic medium according to the invention, a method for producing a hologram by means of pulsed laser radiation, and the use of a holographic medium according to the invention for recording holograms.

A newer and commercially available holographic photopolymer is the “Bayfol HX” film developed by Bayer Materialscience. This does not contain a thermoplastic binder but a polyurethane as the polymer matrix that holds the holographically exposable writing monomers. The polyurethane is formed by polyaddition from a polyisocyanate and polyol mixture. The reactive components are mixed together just before coating and cure on the carrier film. Although there is no high solvent content as with the previously described binder-containing materials, the curing time of up to one hour poses the same problem of providing a sufficiently long dust-free drying or curing section in the coating system.

As with all commercially available photopolymer films, the user cannot freely choose the carrier material and coat it himself, but must process the film structure supplied. In addition to the carrier film, there is also a laminating film on the light-sensitive film layer to prevent adhesion and contamination. Peeling off this film can cause a static charge that attracts dust particles. Since the film must be laminated to either glass or a master for exposure, where every particle of dust creates a flaw, an extremely dust-free environment is required for clean and flawless processing.

Photopolymer systems containing a polymeric binder or polymeric matrix form an essentially solid film layer. In contrast, binder-free systems that are essentially liquid until exposure have also been presented (see, for example, U.S. Pat. No. 3,993,485 A or N. Smirnova, Optics in Information Systems, February 2004, p. 9 or Xetos (see WO 2003036389 A1).

In most essentially solid monomer-binder/matrix photopolymers, unexposed writing monomers located in the area of the dark interference lines diffuse into the exposed polymerised areas after holographic laser exposure. This creates a refractive index difference whose spatial modulation corresponds to the interference pattern to be recorded. However, the diffusion of the writing monomers in the solid matrix takes time. An increase in temperature can accelerate this process. DuPont specifies an annealing time of one hour at 120° C. for the OmniDex® material mentioned. In the case of the Bayfol HX material, the patent applications (EP 2 372 454 A1 p.13 [0127], EP 2 219 073 A1 p.15 [0102]) specify a waiting time of 5 minutes before the material is finally completely cured with UV light.

For many production processes, however, the shortest possible times or the highest throughput and simple, cost-effective process control are required for the production of the holograms, so that cumbersome and time-consuming post-treatments or waiting times are a disadvantage.

For this reason, photopolymerizable compositions were developed that form an effective refractive index modulation already during laser exposure and can be immediately fixed with UV light, as described in EP 1 779 196 B1. Various triglycerides, such as castor oil, were used there.

Storage capability plays a crucial role in the known photopolymerizable compositions due to light sensitivity and the presence of initiators, as it is desirable to always provide the same quality.

A disadvantage of the above-mentioned liquid photopolymerizable composition EP 1 779 196 B1 is that the borate salt used as co-initiator, SEC-LCA 1460 from BASF (formerly CGI 7460 from Ciba), tends to crystallise out after some time. It has a melting point of 80° C. By heating and stirring, the borate can be brought back into solution, but there is a risk of thermally initiated polymerisation or a decrease in photosensitivity due to thermal reactions of the dye. Especially if, for example, methylene blue is used as the dye or additives such as NPG (N-phenylglycine) are used to increase the light sensitivity or thermally activatable initiators such as peroxides (tert-butylperoxybenzoates) are used to increase the reaction rates, which can react sensitively to higher temperatures, enter into chemical reactions, decompose, bleach out, cause turbidity or initiate a radical polymerisation.

The addition of solvents in higher quantities, which would keep the borate in solution for a longer period of time, is counterproductive, as this would impair the holographic quality of the photopolymerizable composition or the rapid processability.

### SUMMARY OF THE INVENTION

The present invention is thus based on the object of providing a holographic system that avoids the disadvantages of known recording materials and, in particular, enables a longer improved storage time or usability period and yet simple and very fast processing. The holographic elements produced from the recording material should also have the highest possible refractive index modulation and a high long-term stability as well as thermal and mechanical stability and should be particularly transparent, clear and not cloudy.

In addition, it must be ensured that the photopolymerizable compositions produced from the kit-of-parts allow a layer-by-layer exposure without the lower already cured layers being attacked by the freshly applied wet layer and deteriorating their mechanical, optical and holographic quality.

In particular, the invention is intended to enable the user to coat his own carrier materials or products and to expose them holographically shortly thereafter without any necessary waiting times.

The object is solved according to the invention by a kit-of-parts for the preparation of a photopolymerizable composition by means of UV/Vis irradiation, comprising:
I) a dye concentrate comprising
   A) a first mixture A, in particular liquid mixture A, comprising
      (f) at least one dye; and
      (h) at least one solvent
      and
II) a liquid composition comprising:
   B) a monomer-containing liquid mixture B comprising:
      a) at least one monomer M1 comprising at least one ethylenically unsaturated group,
      c)at least one co-photoinitiator,
   wherein more than 80% of all components of the solvent in the kit-of-parts or in the dye concentrate have a vapour pressure of≤2 h Pa at 20° C. and a boiling point of≥100° C. at standard pressure, and
   wherein a polymer which is liquid under standard pressure is contained in the solvent and wherein, after mixing of the photopolymerizable composition, it is immediately processable and exposable.

### BRIEF DESCRIPTION OF THE DRAWINGS

FIG. 1 shows a photo of two mixtures of liquid composition II);

FIG. 2 shows a device for producing the hologram made from the kit-of-parts of the present invention;

FIG. 3 shows the schematic exposure setup;

FIG. 4 shows the beam path; and

FIG. 5 shows the measurement curve with the corresponding measurement points of the first exposure of sample H.

### DESCRIPTION OF THE INVENTION

Preferred is also a kit-of-parts for the preparation of a photopolymerizable composition by means of UV/Vis irradiation, wherein the first mixture A further comprises:
(g) at least one photoinitiator; and
wherein the photoinitiator can form radicals under irradiation with a wavelength between 100 nm and 480 nm.

Preferably, more than 90% and more preferably more than 98% of all components of the solvent in the kit-of-parts according to the invention or in the dye concentrate have a vapour pressure of≤2 hPa, preferably≤1.3 hPa and more preferably≤0.2 hPa, at 20° C.

In addition, more than 80%, preferably more than 90% and particularly preferably 95% of the solvent components have a boiling point of≥100° C. at standard pressure. The percentages result from the weight ratio of the components to the total weight of the solvent.

According to the invention, the solvent contains a polymer that is liquid under standard pressure. The polymer preferably comes from the group consisting of polyethylene glycols (PEGs), polycaprolactones, acrylate block copoylmers (EFKA) and poly(bisphenol A-co-epichlorohydrins) (EPI).

The provision of the kit-of-parts according to the invention makes it possible for the photopolymerizable composition to be immediately processable and exposable after mixing.

Preferably, the monomer-containing liquid mixture B is liquid at a standard pressure in the range of 15° C. to 120° C.

For the kit-of-parts it proves advantageous to use a dye concentrate A (also called I)) with a solvent, in particular one with a content of more than 50% by weight, preferably more than 65% by weight, particularly preferably more than 80% by weight of high molecular weight, non-volatile components, including the photoinitiators. This is added to the liquid composition II) (also called II)) to obtain a photopolymerizable composition (also called photopolymer) which can be applied and exposed immediately after mixing. In addition, there are advantageously no waiting times and temporal changes in the material properties due to evaporation and changes in the concentration of the solvent components, so that no vapours harmful to health or the environment can be produced.

By keeping the dye concentrate A as I) and the liquid composition B as II) separate, the shelf life is improved and storage can be simplified, as components A) and B) are less sensitive to light and heat than the photopolymerizable compositions.

In particular, the liquid composition II) can be heated and stirred for a longer period of time without problems, e.g. in order to bring undissolved or crystallised components, such as the borate salt, back into solution.

Preferably, the liquid composition II) is not light sensitive at all and can be easily visually inspected, heated and stirred without any precautions, such as maintaining a certain ambient lighting. This facilitates quality control and the detection of undissolved or crystallised components, as well as processing.

Advantageously, the color is used to set the light to which the kit-of-parts is sensitive. In order to absorb the energy of the light, the complementary color tone of the exposure wavelength is usually selected. For example, a magenta shade is used for a green light, a blue shade for red and a yellow shade for blue. Combinations are also possible for exposure with different wavelengths.

Preferably, the kit-of-part consists of the liquid composition II), which is most preferably a clear, colorless and liquid monomer-containing mixture, and the dye concentrate I). The dye concentrate is preferably added in amounts of 0.5-50% by weight, preferably of 1-10% by weight and particularly preferably of 1-5% by weight, based on the total amount of the kit-of-part, in particular of the liquid composition II), and mixed by stirring, shaking or swirling.

The resulting photopolymerizable composition can be exposed immediately after application to a substrate. The wet application of the composition onto the substrate can be done by squeegee, doctor blade or slot-dye coating. For thin layers smaller than 20 μm, known printing processes such as screen, gravure, engraving, pad or flexographic printing can also be used. Preferably, the material is laminated directly onto the master to be copied using a transparent and clear film. The layer thickness is adjusted either by the contact pressure and the lamination speed or via the slit width. When coating thick and rigid substrates such as glass plates, a spin coating process can be used. Application with an inkjet printing process or with a CNC-controlled dispensing device is also possible. Direct injection into cavities is also possible.

In particular, the liquid material is also suitable for application on curved surfaces. It can also be pressed between two matching bodies and used simultaneously as a kit or adhesive.

The mixing of the kit-of-parts components can take place in the coating plant. For mixing, all mixing techniques and processes known to those skilled in the art can be used, such as stirred tanks, magnetic stirrers, stirring rods, speed mixers and as well as dynamic and static mixers.

After mixing, the additional usual processes known to the skilled person, such as filtration and degassing, can be used.

If it is technically advantageous, a 1:1 or 1:2 variant can also be offered, for example. In this case, the dye concentrate A is stretched to the desired ratio with a dilution mixture.

The dilution mixture contains the components and monomers known from the liquid composition II) without the critical components which, like the borate salt, must be brought back into solution by heating after prolonged storage. The monomer-containing liquid mixture B must then instead contain several times the usual amount of the critical components or the borate salts corresponding to the ratio.

After exposure, the layer is solid. Preferably, no thermal or chemical post-treatment is required after exposure for the photopolymerizable compositions prepared from the kit-of-parts.

By dispensing with substances that first have to evaporate or chemically react after addition or coating, it is ensured that a period of less than 30 minutes, preferably less than 10 minutes, particularly preferably less than 2 minutes, can be used between mixing, application and exposure. On the other hand, this makes it possible that the layer does not have to be applied openly, but can be applied in intermediate spaces or laminated with a covering film. This circumstance significantly simplifies the process for the production of holograms and enables very compact machines.

The short processing time, the short transport distances and the possibility to expose immediately and quickly after application also reduce the requirements for ambient light. This simplifies the set-up and operation of the machine, as it does not have to be elaborately protected from light incidence and does not necessarily have to be located in an extra darkened room.

The user also has the free choice of which substrate materials and layer structures to use, as the coating is done in the exposure unit. After application, exposure can take place immediately. Multi-layer exposures are also no problem, as a new layer can be applied and holographically exposed after curing according to the same principles. This can be used, for example, to build up true-color holograms from three layers for the primary colors red, green and blue.

The photopolymerizable composition from the kit-of-parts is particularly suitable for making contact copies. Because the liquid photopolymerizable composition from the kit-of-parts is printed directly onto the master, index matching is not necessary. This is the application of a liquid between the master and the hologram film with approximately the same refractive index of the two layers. Index matching prevents the occurrence of disturbing interference phenomena (Newton rings) in the normal contact copying process. These are caused by reflections that occur especially in places where the two layers do not touch directly, e.g. due to a dust inclusion or a small unevenness, resulting in bubbles or air inclusions. In addition, the compensation of scratches and other unevenness from the substrate and master improves the optical quality of the copy. Small dust particles with a dimension smaller than the layer thickness are embedded in the liquid and do not produce significant print and defect marks as with film materials. This significantly reduces waste and cleanroom demands on the production environment.

Advantageously, the liquid photopolymerizable composition from the kit-of-parts can thus also be used as an index match material for the exposure of holographic film materials. Because it hardens during exposure, there is no need for cleaning or evaporation. In addition, the holographic recording is supported and enhanced by the combination of the two holographic recording materials, as a hologram is created in both layers. By freely choosing the dye concentrate used, the user can decide which wavelength or colour range is pushed in the combination.

Because the photopolymerizable composition from the kit-of-parts adapts to any surface, in contrast to the film materials, surface structures can be moulded at the same time as the hologram exposure and complex shaped surfaces can be used. The surface structures can be, in particular, embossed holograms or Fresnel structures. This makes it possible to physically and holographically copy both the surface structure and the volume holographic or optical information of the master in a single processing step.

In this way, optical elements such as prisms or lenses with integrated hologram structures can also be produced.

### Dye

The dye serves as a sensitising agent for the co-photoinitiator. Suitable for this purpose are, for example, methylene blue and the sensitising agents disclosed in U.S. Pat. Nos. 3,554,753 A, 3,563,750 A, 3,563,751 A, 3,647,467 A, 3,652,275 A, 4,162,162 A, 4,268,667 A, 4,454,218 A, 4,535,052 A and 4,565,769 A, as well as the dyes and co-photoinitiators mentioned in application WO 2012062655 A2, which are expressly referred to herein. Particularly preferred sensitising agents include the following: DBC, i.e., 2,5-bis[(4-diethylamino-2-methylphenyl)methylene]cyclopentanone; DEAW, i.e., 2,5-bis[(4-diethylaminophenyl)methylene]cyclopentanone; dimethoxy-JDI, i.e., 2,3-dihydro-5,6-dimethoxy-2-[(2,3,6,7-tetrahydro-1H,5H-benzo[i,j]quinolizin-9-yl)methylene]-1H-inden-1-one; and safranin O, i.e., 3,7-diamino-2,8-dimethyl-5-phenyl-phenazinium chloride.

Preferably, the dye in the kit-of-parts according to the invention is a fluorescent dye, which may for example consist of a cationic dye and an anion. The cationic dye can be represented by the formula F⁺.

Therefore, a cationic dye of the formula F⁺ is preferably understood to be one of the following formulae:

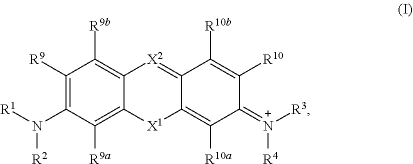

wherein
X¹ represents O, S, N—R⁶ or CR^{6a}R^{6b},
X² represents N or C—R⁵,
R⁵ represents hydrogen, cyano, C₁- to C₄-alkyl, C₄- to C₇-cycloalkyl, C₆- to C₁₀-aryl optionally substituted by C₁- to C₄-alkoxycarbonyl or NR⁷R⁸, a heterocyclic radical or C₆- to C₁₀-aryl substituted by a carboxyl group,
R⁶ represents hydrogen, C₁- to C₁₆-alkyl, C₄- to C₇-cycloalkyl, C₇- to C₁₆-aralkyl, C₆- to C₁₀-aryl or a heterocyclic radical,
R^{6a} and R^{6b} independently of one another represent methyl, ethyl or together represent a —CH₂—CH₂—CH₂— or —CH₂—CH₂—CH₂—CH₂— bridge or represent C₆- to C₁₀-aryl substituted with a carboxyl group,
R¹ to R⁴, R⁷ and R⁸ independently of one another represent hydrogen, C₁- to C₁₆-alkyl, C₄- to C₇-cycloalkyl, C₇- to C₁₆-aralkyl, C₆- to C₁₀-aryl or a heterocyclic radical or
NR¹R², NR⁷R⁴ and NR⁷R⁸ independently of one another represent a five- or six-membered saturated ring which is attached via N and which may additionally contain an N or O and/or may be substituted by nonionic radicals, or
R¹ to R⁴, R⁷ and R⁸ independently of one another form a two- or three-membered bridge with a C atom of the benzene ring adjacent to the N atom, which bridge may contain an O or N and/or may be substituted by nonionic radicals,

R⁹, R^{9a}, R^{9b}, R¹⁰, R^{10a} and R^{10b} independently of one another represent hydrogen, halogen or C₁ to C₄-alkyl,

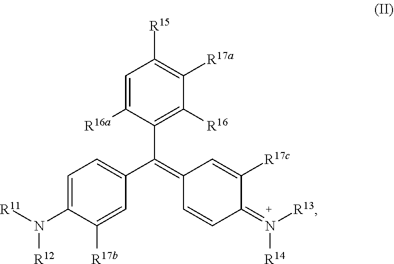

wherein
R¹⁵ represents hydrogen, halogen, C₁- to C₄-alkyl, C₁- to C₄-alkoxy or NR¹⁸R¹⁹,
R¹¹ to R¹⁴, R¹⁸ and R¹⁹ independently of one another represent hydrogen, C₁ to C₁₆-alkyl, C₄- to C₇-cycloalkyl, C₇- to C₁₆-aralkyl, C₆- to C₁₀-aryl or a heterocyclic radical or
NR¹¹R¹², NR¹³R¹⁴ and NR¹⁸R¹⁹ independently of one another represent a five- or six-membered saturated ring which is attached via N and which may additionally contain an N or O and/or may be substituted by nonionic radicals, or
R¹²; R^{17b}; R¹³; R^{17c}; and R¹⁸; R^{17a} independently of one another form a two- or three-membered bridge which may contain an O or N and/or may be substituted by nonionic radicals,
R¹⁶ represents hydrogen, chlorine, methyl, methoxycarbonyl or ethoxycarbonyl,
R^{16a} represents hydrogen, chlorine or methyl,
R^{17a}; R^{17b} and R^{17c} independently of one another represent hydrogen, chlorine, methyl or methoxy.

Non-ionic radicals are C₁- to C₄-alkyl, C₁- to C₄-alkoxy, halogen, cyano, nitro, C₁- to C₄ -alkoxycarbonyl, C₁- to C₄-alkylthio, C₁- to C₄-alkanoylamino, benzoylamino, mono- or di- C₁- to C₄-alkylamino.

Alkyl, alkoxy, cycloalkyl, aryl and heterocyclic radicals may optionally carry further radicals such as alkyl, halogen, nitro, cyano, CO—NH₂, alkoxy, trialkylsilyl, trialkylsiloxy or phenyl, the alkyl and alkoxy radicals may be straight-chain or branched, the alkyl radicals may be partially or perhalogenated, the alkyl and alkoxy radicals may be ethoxylated or propoxylated or silylated, adjacent alkyl and/or alkoxy radicals on aryl or heterocyclic radicals may together form a three- or four-membered bridge and the heterocyclic radicals may be benzo-fused and/or quaternised.

By halogen is meant fluorine, chlorine, bromine or iodine, preferably fluorine, chlorine or bromine.

Examples of substituted alkyl groups are trifluoromethyl, chloroethyl, cyanomethyl, cyanoethyl, methoxyethyl, examples of branched alkyl groups are isopropyl, tert-butyl, 2-butyl, neopentyl. Examples of alkoxy radicals are methoxy, ethoxy, methoxyethoxy.

Preferred optionally substituted C₁- to C₄-alkyl radicals are methyl, ethyl, n-propyl, isopropyl, n-butyl, 2-butyl, iso-butyl, tert-butyl, perfluorinated methyl, perfluorinated ethyl, 2,2-trifluoroethyl, 3,3,3-trifluoroethyl, perfluorobutyl, cyanoethyl, methoxyethyl, chloroethyl.

The preferred aralkyl is, for example, benzyl, phenethyl or phenylpropyl.

Examples of C₆- to C₁₀-aryl are phenyl and naphthyl. Examples of substituted aryl radicals are tolyl, chlorophenyl, dichlorophenyl, methoxyphenyl, nitrophenyl, cyanophenyl, dimethylaminophenyl, diethylaminophenyl.

Examples of hetaryl radicals, especially five- or six-membered heterocyclic radicals, are indolyl, pyridyl, quinolyl, benzthiazolyl. Examples of substituted heterocyclic radicals are 1,2-dimethylindo1-3-yl, 1-methyl-2-phenylindo1-3-yl.

Anions for the cationic dyes of the formula F⁺ can be, for example, anions of halogens, sulphates, carbonates or nitrates.

Particularly suitable cationic dyes are malachite green, methylene blue, safranin O, rhodamines of the formula III

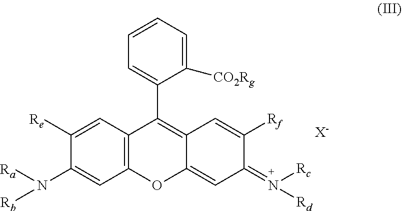

wherein Rₐ, R_{b}, R_{c}, R_{d}, Rₑ, R_{f} and R_{g} each represents H or an alkyl group, and X⁻ represents chloride ion, trifluoromethanesulfonate, naphthalene disulfonate, para-toluenesulfonate, hexafluorophosphate, perchlorate, meta-nitrobenzenesulfonate or meta-amino-benzenesulfonate, for example rhodamine B, rhodamine 6 G or violamine R, further sulforhodamine B or sulforhodamine G as listed below.

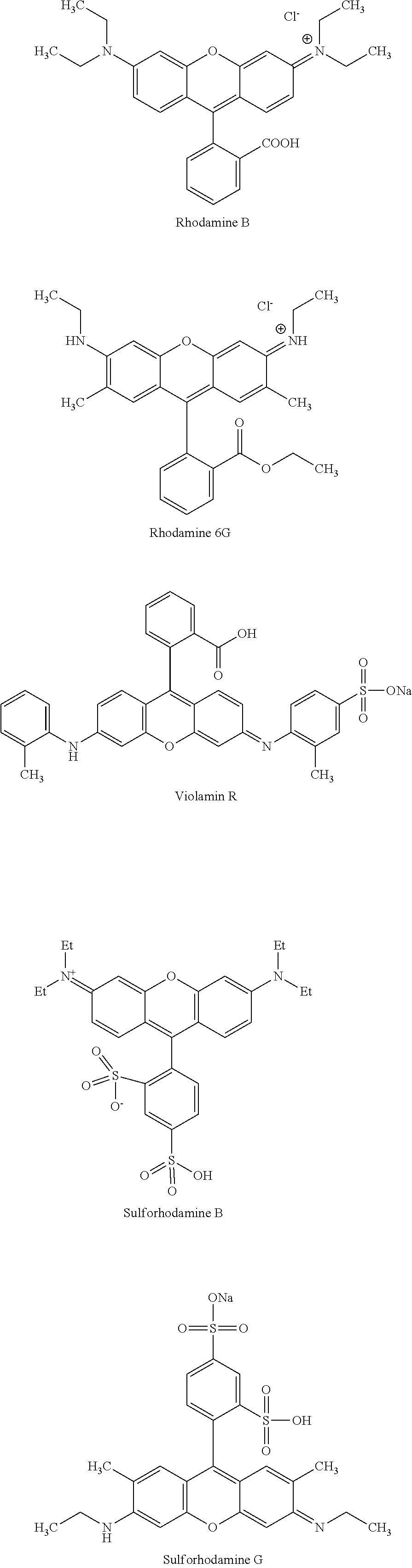

Other suitable dyes are fluorones, as described e.g. by Neckers et al. in J. Polym. Sci., Part A, Poly. Chem, 1995, 33, 1691-1703. Particularly interesting is

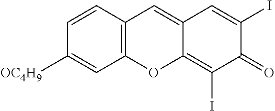

Examples of other suitable dyes are cyanines of the formula IV

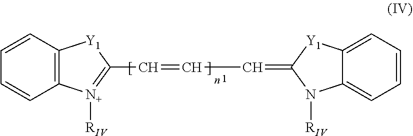

wherein R_{IV}=alkyl; n¹=0, 1, 2, 3 or 4 and Y₁=CH═CH, N—CH₃, C(CH₃)₂, O, S or Se. Preferred are cyanines wherein Y1 in formula IV is C(CH₃)₂ or S.

Preferably, the dye in the kit-of-parts according to the invention is selected from the group consisting of acriflavins, diaminoacridins, rhodamine B, safranin-O, diethylsafranin and methylene blue.

### Solvent for the Dye

Ethanol, propanol, iso-propanol, butanol, iso-butanol, tert-butanol, pentanol, iso-pentanol, tert-pentanol, hexanols, heptanols, glycols, diglycol, triglycol.

Water, methanol, ethanol, propanol, butanol, ketones, acetone, methyl ethyl ketone, ether, tetrahydrofuran, 1,4-dioxane, trioxane,

Triethanolamine (TEA), castor oil, castor oil glycidyl ether, octanoic acid, tert-butyl peroxybenzoate, 2-dimethylaminoethanol, anisole, poly(ethylene glycol) block-poly(propylene glycol) block-poly(ethylene glycol), benzyl alcohol, tetrachloroethylene, dipropylene glycol dimethyl ether, dichloromethane, acetic anhydride, propylene carbonate, acetic acid n-butyl ester, cyclohexane, cyclopentanones, ethylene glycol, polyethylene glycols, toluene, eucalyptus oil, glycolic acid butyl ester (Polysolvan-O), N-methyl-2-pyrrolidone (NMP), propylene glycol monomethyl ether acetate (PGMEA), poly(bisphenol A-co-epichlorohydrin), trimethylol propane ethoxy triacrylate (TMPEOTA), trimethyol propane triacrylate (TMPTA), tripropylene glycol diacrylate (TrPGDA), N,N-dimethylacrylamide.

Preferred, dimethyl sulphoxide (DMSO), N,N′-dimethylpropylene urea, N-hydroxyethylacrylamide (HEAA), benzaldehyde, polycaprolactone (PolyCLO, Capromer PT-05), polycaprolactone triol, polyethylene glycol (PEG-200), acrylic block copolymer (Efka PX 4701).

It turned out to be particularly advantageous that UV photoinitiators, which are needed in the photopolymerizing composition anyway, can surprisingly also be used as good solvents for the dyes.

They are described below, preferably the liquid photoinitiators Omnirad 1173, Omnirad MBF, Omnirad 1000 and Omnirad TPO-L are used. However, the addition of UV initiators in powder form at room temperature to the solvent mixture can also increase the solubility of the dyes.

Preferably, the solvent contains a polymer that is liquid under standard pressure. Advantageously, the polymer that is liquid under standard pressure can be selected from the group consisting of polyethylene glycols (PEGs), polycaprolactones, acrylate block copoylmers (EFKA) and poly(bisphenol A-co-epichlorohydrins) (EPI).

It is particularly advantageous if the substances mentioned do not worsen the properties, such as the diffraction efficiency, of the material mixed together from the two kit-of-parts components. If they even contribute to an improvement, then they can also be used as an additive in the monomer-containing liquid mixture B.

### Photoinitiator

Preferably, the photoinitiator in the kit-of-parts according to the invention, can form radicals under irradiation with a wavelength between 100 nm and 480 nm, preferably between 150 nm and 460 nm and particularly preferably between 200 nm and 380 nm.

These photoinitiators can be present in the kit-of-part according to the invention both in the first mixture A (dye concentrate) and in the monomer-containing liquid mixture B.

The kit-of-parts according to the invention comprises a first mixture A, preferably a first liquid mixture A, comprising at least one photoinitiator which preferably activates the polymerisation of the monomer(s) M1 or M2 upon exposure to (actinic) radiation. This is preferably a radical-forming polymerisation initiator.

Actinicity (actinic radiation) can be understood as the photochemical activity of electromagnetic radiation of different wavelengths.

The term is used, for example, in evaluating the physiological consequences of laser light of different colors or the spectral sensitivity of photographic films and papers. In photochemistry, actinic chemicals are those that are sensitive to light or radiation.

Radical-forming polymerisation initiators are known, see e.g. Timpe, H. J. and S. Neuenfeld, “Dyes in photoinitiator systems”, Kontakte (1990), pages 28-35 and Jakubiak, J. and J. F. Rabek, “Photoinitiators for visible light polymisation”, Polimery (Warsaw) (1999), 44, pages 447-461.

Suitable radical-forming polymerisation initiators that can be activated by UV radiation and are generally inactive at temperatures up to 185° C. include the substituted or unsubstituted polynuclear quinones; these are compounds with two intracyclic carbon atoms in a conjugated carbocyclic ring system, e.g. 9,10-anthraquinone, 1-chloroanthraquinone, 2-chloroanthraquinone, 2-methylanthraquinone, 2-ethylanthraquinone, 2-tert-butylanthraquinone, octamethylanthraquinone, 1,4-naphthoquinone, 9,10-phenanthrenequinone, 1,2-benzanthraquinone, 2,3-benzanthraquinone, 2-methyl-1,4-naphthoquinone, 2,3-dichloronaphthoquinone, 1,4-dimethylanthraquinone, 2,3-dimethylanthraquinone, 2-phenylanthraquinone, 2,3-diphenylanthraquinone, sodium salt of anthraquinone α-sulfonic acid , 3-chloro-2-methylanthraquinone, retenquinone, 7,8,9,10-tetrahydronaphthacenequinone and 1,2,3,4-tetrahydrobenz[a]anthracene-7,12-dione. Other photoinitiators are also useful, although some are thermally active at temperatures as low as 85° C., are described in U.S. Pat. No. 2,760,663 A, and include vicinal ketaldonyl alcohols such as benzoin, pivaloin, acyloin ethers, e.g. benzoin methyl and ethyl ethers, α-hydrocarbon-substituted aromatic acyloins, including α-methylbenzoin, α-allylbenzoin, and α-phenylbenzoin

Photoreducible dyes and reducing agents such as those disclosed in U.S. Pat. Nos. 2,850,445 A, 2,875,047 A, 3,097,096 A, 3,097,097 A, 3,145,104 A and 3,579,339 A can be used as photoinitiators, as well as dyes from the class of phenazines, oxazines and quinones; Michler's ketone, benzophenone, 2,4,5-triphenylimidazolyl dimers with hydrogen donors and mixtures thereof as described in U.S. Pat. Nos. 3,427,161 A, 3,479,185 A, 3,549,367 A, 4,311,783 A, 4,622,286 A and 3,784,557 A. A useful discussion of dye sensitised photo-polymerization can be found in “Dye Sensitized Photopolymerization” by D. F: Eaton in Adv. in Photochemistry, vol. 13, D. H. Volman, G. S. Hammond and K. Gollnick, eds, Wiley-Interscience, New York, 1986, pp. 427-487. Similarly, the cyclohexadienone compounds of U.S. Pat. No. 4,341,860 are useful as initiators. Suitable photoinitiators include CDM-HABI, i.e., 2-(o-chlorophenyl)-4,5-bis(m-methoxyphenyl)-imidazole dimer; o-CI-HABI, i.e., 2,2bis-′(o-chlorophenyl)-4,4,′5,5′-tetraphenyl-1,1′-biimidazole; and TCTM-HABI, i.e., 2,5-bis(o-chlorophenyl)-4-(3,4-dimethoxyphenyl)-1H-imidazole dimer, each typically used with a hydrogen donor, e.g. 2-mercaptobenzoxazole.

Particularly preferred UV photoinitiators for the liquid composition B) and/or the dye concentrate are IRGACURE® OXE-01 (1,2-octanedione-1-[4-(phenylthio)-phenyl]-2-(O-benzoyloxime) and IRGACURE® OXE-02 (1-[9-ethyl-6-(2-methylbenzoyl)-9H-carbazol-3-yl]ethanone-O-acetyloxime from BASF AG, as well as OMNIRAD-MBF (methylbenzoyl formate), OMNIRAD-TPO (2,4,6-trimethylbenzoyl-diphenyl-phosphine oxide), OMNI-RAD-TPO-L (ethyl-(2,4,6-trimethylbenzoyl)-phenylphosphinate), OMNIRAD-1173 (2-hydroxy-2-methyl-1-phenylpropanone), OMNIRAD 1000 (mixture of 2-hydroxy-2-methyl-1-phenylpropanone (80%) and 1-hydroxycyclohexyl-phenylketone (20%)), OMNIRAD 184 (1-hydroxycyclohexyl-phenylketone), OMNIRAD 819 (bis(2,4,6-trimethylbenzoyl)phenylphosphine oxide), OMNIRAD 2022 (mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate) and OMNICAT 440 (4,4′-dimethyl-diphenyl-iodonium hexafluorophosphate), which are obtainable from IGM Resins and are preferably present in an amount of 0.1 to 10% by weight are used.

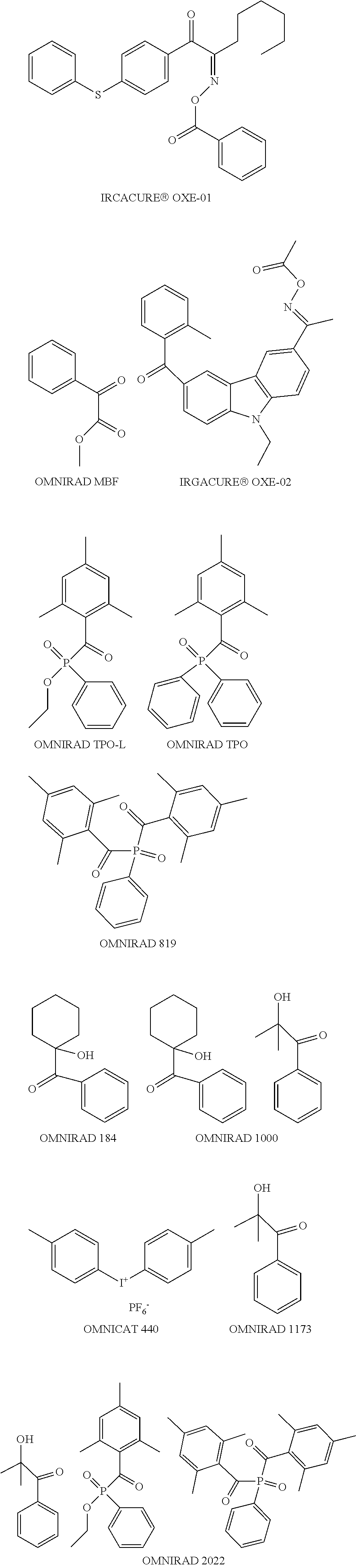

The photoinitiators mentioned above can be used alone or in combination.

Preferably, the photoinitiator is liquid and/or is selected from the group consisting of 1,2-octanedione-1-[4-(phenylthio)-phenyl]-2-(O-benzoyloxime), (1-[9-ethyl-6-(2-methylbenzoyl)-9H-carbazol-3-yl]ethanone-O-acetyloxime, methylbenzoyl formate), 2,4,6-trimethylbenzoyl diphenyl phosphine oxide, ethyl (2,4,6-trimethylbenzoyl) phenyl phosphinate), 2-hydroxy-2-methyl-1-phenyl propanone, a mixture of 2-hydroxy-2-methyl-1-phenylpropanone (80%) and 1-hydroxycyclohexyl-phenylketone (20%), 1-hydroxycyclo-hexyl-phenylketone, bis(2,4,6-trimethylbenzoyl)phenylphosphine oxide, a mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate), and 4,4′-dimethyl-diphenyl-io-donium hexafluorophosphate.

Preferably, solid photoinitiators are used in the liquid composition and liquid photoinitiators in the dye concentrate.

### Monomer M1

The liquid composition II) of the kit-of-parts comprises a mixture B comprising at least one monomer M1 comprising at least one ethylenically unsaturated group, and preferably a monomer M2 comprising at least two ethylenically unsaturated groups, M2 preferably differing from M1 only by the second ethylenically unsaturated group.

The monomer M1 comprising at least one ethylenically unsaturated group may have the following general structural units.

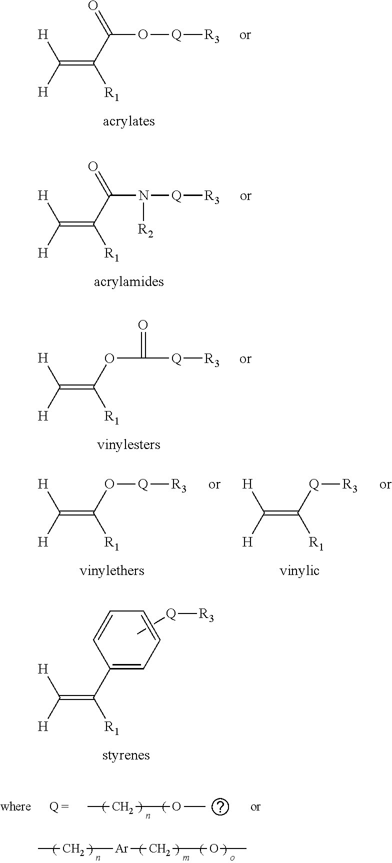

wherein n, m=0-12, preferably 1-12; o=0, 1; and Ar is a mono- or polynuclear substituted or unsubstituted aromatic or heterocyclic aromatic radical,
where the radical R¹ is H, methyl or ethyl and
wherein the radicals R² and R³ are independently selected from the group consisting of alkyl, alkenyl, alkynyl, alkoxy, acyl and acyloxy radicals which may be straight or branched chain, unsubstituted or substituted, substituted or unsubstituted aryloxy radicals, substituted or unsubstituted aromatic radicals or heterocyclic radicals, unsubstituted or substituted alicyclic hydrocarbon radicals, aliphatic, aromatic and aliphatic-aromatic amino, carboxylic acid, amido and imido radicals, hydroxy, amino, cyano, nitro, halogen atoms or hydrogen atoms, and combinations of the foregoing radicals, wherein the substituted radicals may be substituted with C₁-C₁₂ alkyl, C₁-C₁₂ alkoxy, hydroxy, carboxy, carbonyl, amino, amido, imido radicals, halogen atoms, aromatic radicals or combinations thereof.

Examples of suitable monomers M1 are substituted or unsubstituted styrene monomers, acrylic acid, α-alkylacrylic acid, acrylic esters, α-alkylacrylic esters,in which their alcohol component may be a substituted or unsubstituted aliphatic or aromatic radical containing 2-50 carbon atoms, acrylamides, α-alkyl acrylamides , wherein alkyl is as defined above, vinyl esters, vinyl alcohol, vinyl ethers and other substituted vinyl monomers substituted with substituted or unsubstituted aliphatic or aromatic radicals having 2-50 carbon atoms.

Preferred examples of suitable monomers M1 are (meth)acrylic acid butyl ester, (meth)acrylic acid phenyl ester, (meth)acrylic acid benzyl ester, (meth)acrylic acid isobornyl ester, (meth)acrylic acid cyclohexyl ester, (meth)acrylic acid 2-phenoxyethyl ester, (meth)acrylic acid 1H,1H,2H,2H-perfluorooctyl ester, 2,2,2-trifluoroethyl (meth)acrylate, heptafluoropropyl (meth)acrylate, 1,1,1,3,3,3-hexyfluoroisopropyl (meth)acrylate, 2,2,3,3-tetrafluoropropyl (meth)acrylate), 2,2,3,3,4,4,4-heptafluorobutyl (meth)acrylate, 2,2,3,3,4,4,5,5-octafluoropentyl (meth)acrylate, acrylic acid N,N-diethylaminoethyl ester, acrylic acid ethoxyethyoxyethyl ester, acrylic acid 2-(p-chlorophenoxy)ethyl ester, p-chlorophenyl acrylate, 2-phenylethyl (meth)acrylate, pentachlorophenyl acrylate, phenyl acrylate, p-chlorostyrene, n-vinylcarbazole, 1-vinyl-2-pyrolidone, 2-chlorostyrene, 2-bromo-styrene, methoxystyrene, phenol ethoxylate acrylate, 2-(p-chlorophenoxy)ethyl acrylate, 2-(1-naphthyloxy)ethyl acrylate, hydroquinone monomethacrylate and 2-[β-(N-carbazolyl)propionyloxy]ethyl acrylate.

Particularly preferred monomers M1 are N-vinylcarbazole, ethoxyethoxyethyl acrylate, 2-naphthyl acrylate, 2-phenoxyethyl acrylate, 2-phenoxyethyl methacrylate, phenol ethoxylate acrylate, 2-(p-chlorophenoxy)ethyl acrylate, p-chlorophenyl acrylate, phenyl acrylate, 2-phenylethyl acrylate, 2-(1-naphthyloxy)ethyl acrylate, t-butyl acrylate, isobornyl acrylate, cyclohexyl acrylate, N,N-diethylaminoethyl acrylate, acrylamide, ethoxyethoxy-ethyl acrylate, 1H,1H,2H,2H-perfluorooctyl methacrylate and pentafluoroethyl acrylate.

Preferably, the monomer M1 comprises at least two ethylenically unsaturated groups, hence the monomer is preferably difunctional.

Difunctional ethylenically unsaturated monomers have two C—C double bonds in the molecule, i.e. they contain e.g. two of the structural units indicated above. A difunctional ethylenically unsaturated monomer may contain, for example, two acrylate or methacrylate groups.

The monomer M1 in the monomer-containing liquid mixture B according to the invention may consist exclusively of one or more difunctional or higher functional monomers, i.e. the composition may be free of monofunctional ethylenically unsaturated monomers. Preferably, the content of monomers M1 having at least two ethylenically unsaturated groups in the mixture B is more than 10% by weight, particularly preferably the content of monomers M1 having at least two ethylenically unsaturated groups is more than 20% by weight.

The use of difunctional or higher functional monomers leads in particular to a particularly high thermal and mechanical stability of the produced holographic elements and is especially advantageous in the production of refexion holograms.

Preferred monomers M1 having at least two ethylenically unsaturated groups are ethoxylated bisphenol A diacrylates, in particular compounds of the following formula

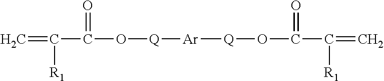

wherein R¹, Q and Ar have the meaning given above.

A particularly preferred monomer M1 is the compound of the following structural formula:

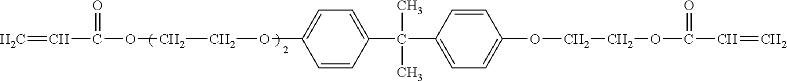

Preferably, the viscosity of the monomer M1 or monomer mixture is at least 900 mPa·s at room temperature.

The viscosity of the liquid composition II) is also at least 900 mPa·s at 20° C., preferably 1500 mPa·s and particularly preferably at least 2000 mPa·s.

The viscosity can be determined with a plate-plate rotational rheometer (e.g. from Haake, type 006-2805). The material is placed between two coaxial, circular plates, one of which rotates. The plates have a distance of e.g. 1 mm and a diameter of 35 mm. The viscosity can be determined from the measurement of the torque and the speed (e.g. 10 revolutions/s) (DIN53018, ISO3210).

### Co-Photoinitiator

Preferably, the co-photoinitiator used in the kip-of-parts according to the invention comprises a compound of formula (I)

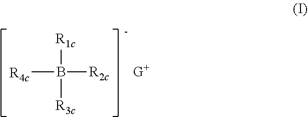

wherein
R^{1c} denotes C₁-C₂₀-alkyl, C₃-C₁₂-cycloalkyl, C₂-C₈-alkenyl, phenyl-C₁-C₆-alkyl or naphthyl-C₁-C₃-alkyl, where the radicals C₁-C₂₀-alklyl, C₃-C₁₂-cycloalkyl, C₂-C₈-alkenyl, phenyl-C₁-C₆-alkyl or naphthyl-C₁-C₃-alkyl can be interrupted with one or more groups O, S(O)ₚ or NR^{5c} or where the radicals C₁-C₂₀-alkyl, C₃-C₁₂-cycloalkyl, C₂-C₈-alkenyl, phenyl-C₁-C₆-alkyl or naphthyl-C₁-C₃-alkyl are unsubstituted or substituted by C₁-C₁₂-alkyl, OR⁶, R^{7c}S(O)ₚ, R^{7c}S(O)₂O, NR^{8c}R^{9c}, SiR^{10c}R^{11c}R^{12c}, BR^{13c}R^{14c} or R^{15c}R^{16c}P(O)_{q}; R^{2c}, R^{3c} and R^{4c} independently of one another are phenyl or biphenyl, the phenyl or biphenyl radicals being unsubstituted or substituted by unsubstituted or by OR^{6c}, NR^{8c}R^{9c} or halogen-substituted C₁-C₁₂-alkyl, OR^{6c}, R^{7c}S(O)ₚ, R^{7c}S(O)₂O, R^{8c}R^{9c}NS(O)₂, NR^{8c}R^{9c}, NR^{3c}R^{8c}CO,

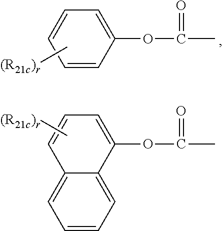

SiR^{10c}R^{11c}R^{12c}, BR^{13c}R^{14c}, Halogen, R^{15c}R^{16c}P(O)_{q},

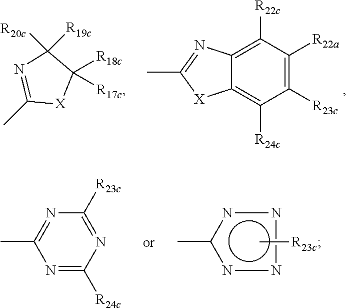

R^{5c} is hydrogen, C₁-C₁₂-alkyl, phenyl-C₁-C₆-alkyl which is unsubstituted or substituted one to five times by C₁-C₆-alkyl, C₁-C₁₂-alkoxy or halogen, or phenyl which is unsubstituted or substituted one to five times by C₁-C₆-alkyl, C₁-C₁₂-alkoxy or halogen;
R^{6c} and R^{7c} denote C₁-C₁₂-alkyl which is unsubstituted or substituted by halogen, phenyl C₁-C₆-alkyl which is unsubstituted or substituted one to five times by C₁-C₆-alkyl, C₁-C₁₂-alkoxy or halogen, or phenyl which is unsubstituted or substituted one to five times by C₁-C₆-alkyl, C₁-C₁₂-alkoxy or halogen;
R^{8c}, R^{9c}, R^{10c}, R^{11c}, R^{12c}, R^{13c}, R^{14c}, R^{15c}, and R^{16c} denote independently of one another C₁-C₁₂-alkyl, C₃-C₁₂-cycloalkyl, phenyl-C₁-C₆-alkyl which is unsubstituted or substituted one to five times by C₁-C₆-alkyl, C₁-C₁₂-alkoxy or halogen, or phenyl which is unsubstituted or substituted one to five times with C₁-C₆-alkyl, C₁-C₁₂-alkoxy or halogen, or R^{8c} and R^{9c} together with the N-atom to which they are bonded form a 6-membered aliphatic ring which may also contain oxygen or sulphur as a further heteroatom;
R^{17c}′, R^{18c}, R^{19c} and R^{20c} denote independently of one another hydrogen, C₁-C₁₂-alkyl which is unsubstituted or substituted by C₁-C₁₂-alkoxy, or phenyl or phenyl-C₁-C₆-alkyl, the radicals phenyl or phenyl-C₁-C₆-alkyl being unsubstituted or mono- to pentasubstituted by C₁-C₆-alkyl, C₁-C₁₂-alkoxy or halogen; p is a number from 0 to 2;
r represents a number from 0 to 5;
R^{21c} represents hydrogen or C₁-C₁₂-alkyl;
R^{22c}, R^{22a}, R^{23c} and R^{24c} independently of one another denote hydrogen, C₁-C₁₂-alkyl which is unsubstituted or substituted by C₁-C₁₂-alkoxy, OH or halogen, or phenyl which is unsubstituted or substituted by C₁-C₁₂-alkoxy, OH or halogen;
q represents either 0 or 1; and
G represents a residue which can form positive ions.

Preferably, the co-photoinitiator in the kit-of-parts according to the invention is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

Very preferably is a co-photoinitiator with the structural formula la, which was developed under the name “CGI 7460” by Ciba Specialty Chemicals Inc. and is now available from BASF AG under the name SEC LCA 1460, which is presented as follows:

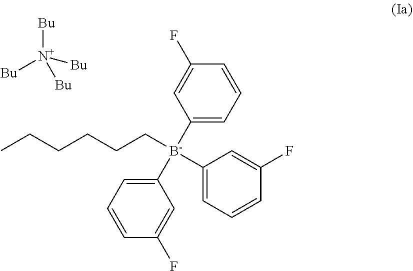

### Additives

In order to adapt the kit-of-parts to the chosen processing method or field of application and to improve printability, surface adhesion, viscosity, film formation, flexibility, hardness, resistance to cold, heat and weathering, the liquid composition or the first mixture A may contain various additives known per se.

Therefore, the dye concentrate or liquid composition optionally comprises an additive.

The additives include fillers, dyes, plasticisers, surfactants, common components used in photopolymer systems, polymeric binders, wetting agents, levelling agents, defoamers, adhesion promoters, surface additives, nanoscale particles, optical brighteners or mixtures thereof.

These should be easy to mix in and should not worsen the diffraction efficiency. Non-volatile substances can even permanently improve the diffraction efficiency in thin layers, especially by choosing additives that increase the refractive index difference between the ethylenically unsaturated monomer and the other components. Therefore, in addition to known polymers with a low refractive index such as polyvinyl acetate, especially fluorinated or silanized polymers can be considered in this case. In order to achieve good diffusion properties, the molecular weight of the additives considered should not be too high.

The additives mentioned above and detailed below can generally be used in an amount of 0.01 to 20% by weight, preferably 0.01 to 10% by weight, with respect to the total amount of the kit-of-parts.

The kit-of-parts may contain a plasticiser to enhance the modulation of the refractive index of the imaged composition. Plasticisers may be used in amounts ranging from about 0.01% to about 10% by weight, preferably from 5% to about 10% by weight, based on the total amount of the kit-of-parts. Suitable plasticizers include triethylene glycol, triethylene glycol diacetate, triethylene glycol dipropionate, triethylene glycol dicaprylate, triethylene glycol dimethyl ether, triethylene glycol bis(2-ethylhexanoate), tetraethylene glycol diheptanoate, polyethylene glycol, polyethylene glycol methyl ether, isopropyl naphthalene, diisopropyl naphthalene,polypropylene glycol, glyceryl tributyrate, diethyl adipate, diethyl sebacinate, dibutyl suberinate, tributyl phosphate, tris(2-ethylhexyl) phosphate, Brij® 30 [C₁₂H₂₅(OCH₂CH₂)₄OH], Brij® 35 [C₁₂H₂₅(OCH₂CH₂)₂₀OH], and n-butyl acetate.

Particularly preferred plasticisers are polyethylene glycol, triethylene glycol diethyl hexanoate (3G8), triethylene glycol dicaprylate, tetraethylene glycol diheptanoate, diethyl adipate, Brij® 30 and tris(2-ethylhexyl) phosphate.

If desired, other common components used in photopolymer systems may be used with the compositions and elements of the present invention. These components include: Optical brighteners, ultraviolet radiation absorbing material, thermal stabilisers, hydrogen donors, oxygen scavengers and release agents. These additives may also include polymers or co-polymers.

Useful optical brighteners include those disclosed in U.S. Pat. No. 3,854,950 A. A preferred optical brightener is 7-(4′-chloro-6′-diethylamino-1′,3′,5′-triazin-4′-yl)amino-3-phenyl-coumarin. Ultraviolet radiation absorbing materials useful in the present invention are also disclosed in U.S. Pat. No. 3,854,950 A.

Useful thermal stabilisers include: Hydroquinone, phenidone, p-methoxyphenol, alkyl- and aryl-substituted hydroquinones and quinones, tert-butylcatechol, pyrogallol, copper resinate, naphthylamines, β-naphthol, copper(I) chloride, 2,6-di-tert-butyl-p-cresol, phenothiazine, pyridine, nitrobenzene, dinitrobenzene, p-toluchinone and chloranil. Also useful are the dinitroso-dimers described in U.S. Pat. No. 4,168,982 A. Typically, a thermal polymerisation inhibitor is also present to increase stability during storage of the photopolymerizable composition.

Hydrogen donor compounds useful as chain transfer reagents include: 2-mercaptobenzoxazole, 2-mercaptobenzothioazole, etc., as well as various types of compounds such as. (a) ethers, (b) esters, (c) alcohols, (d) compounds containing allylic or benzylic hydrogen such as cumene, (e) acetals, (f) aldehydes, and (g) amides, as disclosed in column 12, lines 18 to 58 in U.S. Pat. No. 3,390,996, which is specifically referred to herein.

Compounds that have proven useful as release agents are described in U.S. Pat. No. 4,326,010 A. A preferred release agent is polycaprolactone.

The kit-of-parts may also contain one or more polymeric binders selected from the group comprising polymethyl methacrylate and polyethyl methacrylate, polyvinyl esters such as polyvinyl acetate, polyvinyl acetate/acrylate, polyvinyl acetate/methacrylate and partially hydrolysed polyvinyl acetate, ethylene/vinyl acetate copolymers, vinyl chloride/carboxylic acid ester copolymers, vinyl chloride/acrylic acid ester copolymers, polyvinyl butyral and polyvinyl formal, butadiene and isoprene polymers and copolymers and polyethylene oxides of polyglycols having an average molecular weight of about 1,000 to 1,000,000 g/mol, epoxides, such as epoxides containing acrylate or methacrylate residues, polystyrenes, cellulose esters, such as cellulose acetate, cellulose acetate succinate and cellu-lose acetate butyrate, cellulose ethers, such as methyl cellulose and ethyl cellulose, polycondensates, such as polycarbonates, polyesters, polyamides, such as N-methoxymethyl polyhexamethylene adipamide, polyimides, polyurethanes. The polymeric binders mentioned can be used, for example, in an amount of 0.001 to 10% by weight, based on the total weight of the kit-of-parts.

The kit-of-parts may also include one or more wetting agents (in particular fluorocarbon polymers, such as Schwego-Fluor 8038™, or fluorosurfactants, such as 3M Fluorad FC-4430™) leveling agents (in particular glycolic acid n-butyl esters or polyether-modified polydimethylsiloxanes, such as ADDID 130™), defoamers (in particular fluorosilicone oil-based defoamers, such as ADDID 763™) adhesion promoters (in particular diamino-tri-methoxy-functional silane adhesion promoters, such as ADDID 900™ or glycidyl tri-methoxy trifunctional silane coupling agents, such as ADDID 911™, vinyl triethyoxysilane or 3-methacryloxypropyl trimethoxysilane), or surface additives (in particular polyether-modified acryl-functional polydimethyl siloxanes, such as BYK-UV 3500™, polyether-modified polydimethylsiloxanes such as BYK-UV 3510™ or polyether-modified acryl-functional polydimethylsiloxanes such as BYK-UV 3530™). The products mentioned with the trade names “ADDID” and “BYK” are available from Wacker and BYK Chemie, respectively.

The kit-of-parts may also contain nanoscale particles such as TiO2, SiO2 or Au, which may be coupled to monomers (such materials are available, for example, under the trade name “Nanocryl”).

Preferably, the additive can be an amine synergist. An amine synergist in combination with other photoinitiators can increase the curing speed of UV coatings (see DE 60216490 T2).

Preferably, the additive can be a peroxide. A thermally activatable peroxide, in combination with other photoinitiators, can improve the curing of UV coatings, especially in shaded areas (see U.S. Pat. No. 5,017,406 A or DE 60030223 T2).

Preferably, the additive can also be a marker selected from fluorescent pigments or lanthanide compounds. For example, europium or terbium trisdipicolinate complexes can be used as lanthanide compounds.

For the purposes of the present invention, a marker is understood to be a forensically detectable substance that can be used to determine the authenticity or origin of a product or its producer or seller. Provided that the layers to be produced are thick enough to embed the corresponding microparticles, small individualized particles, colored micro-plastic also known as taggant, can also be introduced.

The liquid composition may further comprise a triglyceride and/or a modified triglyceride.

The suitable triglycerides are generally compounds of the following general structural formula

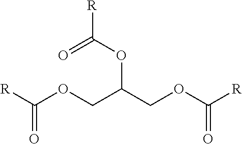

wherein each R, independently of the others, represents a fatty acid residue; preferably each R contains from 6 to 22, more preferably from 8 to 18, carbon atoms.

Naturally occurring oils or fats such as castor oil, coconut oil, palm kernel oil and mixtures thereof can also be used as triglycerides. Derivatives (e.g. hydrogenation products) of such natural fats and oils may also be used. Such naturally occurring oils or fats are or generally contain mixtures of various triglycerides.

A particularly preferred triglyceride is the triglyceride of ricinoleic acid, which is a major constituent of castor oil.

Preferably, the triglyceride is chosen such that the amount of the difference between the refractive index (n) of the ethylenically unsaturated monomer or monomer mixture and the refractive index of the triglyceride (i.e. |n(monomer)−n(triglyceride)|) at 20° C. is at least 0.02, more preferably at least 0.05, most preferably at least 0.07.

For example, ethyoxylated castor oils or their ricinoleic acids can be considered as modified triglyceride. Preferably, the modified triglyceride comprises ethoxylated triglycerides with 25 to 250 units based on ethylene oxide. For example, Hedipin R/2000 also known as “PEG-200 castoir oil”) may be used.

Hedipin R/2000 is prepared by reacting castor oil with ethylene oxide in a molar ratio of 1:200. Castor oil is a mixture of triglycerides obtained from the seeds of Ricinus communis. The main component of castor oil (>80%) is the triglyceride of ricinoleic acid. Hedipin R/2000 contains a mixture of polyethoxylated triglycerides, the polyethoxylated products of the triglyceride of ricinoleic acid being the main constituent. The polyethoxylated products of the triglyceride of ricinoleic acid comprise one or more of the compounds of formula A, B and C and mixtures thereof, as well as all stereoisomers thereof. Other components of Hedipin R/2000 may include polyoxyethylene ricinoleates, free polyethylene glycols and ethoxylated glycerols.

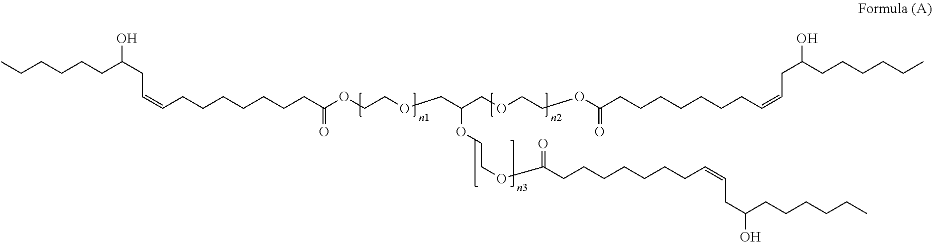

In formula (A), n1, n2 and n3 are independently an integer of 0-200, more preferably of 10-180, more preferably of 20-150, more preferably of 30-130, more preferably of 40-110, more preferably of 50-90, more preferably of 60-75, where n1+n2+n3=150-250.

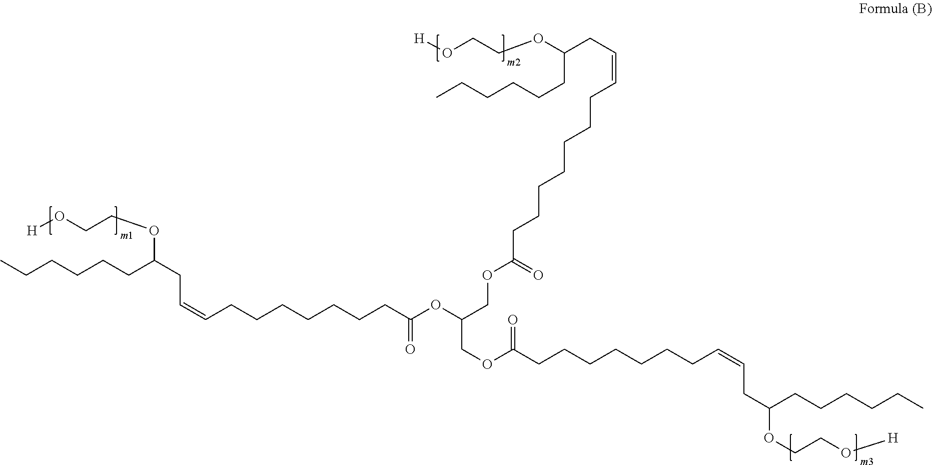

In formula (B), m1, m2 and m3 are independently an integer from 0-200, more preferably from 10-180, more preferably from 20-150, more preferably from 30-130, more preferably from 40-110, more preferably from 50-90, more preferably from 60-75, where m1+m2+m3=150-250.

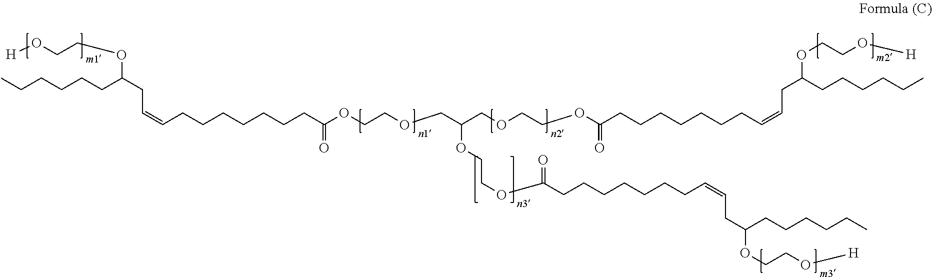

In formula (C), n1′, n2′ and n3′ are each independently an integer of 0-200, more preferably of 5-175, more preferably of 10-150, more preferably of 15-125, more preferably of 20-100, more preferably of 20-75, more preferably of 25-40, where n1′+n2′+n3′=50-150.

In formula (C), m1′, m2′ and m3′ are each independently an integer from 0-200, more preferably from 5-175, more preferably from 10-150, more preferably from 15-125, more preferably from 20-100, more preferably from 20-75, more preferably from 25-40, n1′+n2′+n3′=50-150.

Preferably, in formula (C), n1′, n2′, n3′, m1′, m2′ and m3′ are each independently an integer of 10-150, more preferably of 15-125, more preferably of 20-100, more preferably of 20-75, more preferably of 25-40, where n1′+n2′+n3′+m1′+m2′+m3′=150-250.

The use of triglycerides or modified triglycerides has further advantages: The photopolymerizable composition exhibits reduced surface adhesion and flexibility, as the triglyceride or modified triglyceride simultaneously acts as a release agent and plasticiser. An exposed hologram can therefore be easily and completely removed from a substrate, such as glass or metal. This property is also very favourable for mass production, because it allows wear-free copy masters, such as conventional nickel shims with a fine holographic surface structure or volume holograms sealed with thin glass, to be used for making contact copies. Due to the residue-free removal of the non-sticky layer, the cleaning effort remains low. When the liquid photopolymerizable composition is printed directly onto the master, index matching is also eliminated. This is the application of a liquid between the master and the hologram layer with approximately the same refractive index of the two layers. Index matching prevents the occurrence of disturbing interference phenomena (Newton rings) in the normal contact copying process. These are caused by reflections that occur especially in places where the two layers do not touch directly, e.g. because of a dust inclusion or a small unevenness. Compensating for scratches and other irregularities in the substrate or on the master also improves the optical quality of the copy. Small dust particles with a dimension smaller than the layer thickness are embedded in the liquid and do not create significant print and defect marks as with film materials. This significantly reduces waste and cleanroom demands on the production environment.

The gapless contact between the recording material and the master can also be used to mould existing surface structures on the master. Such surface structures can be embossed holograms or Fresnel structures in particular. This makes it possible to copy both the surface structure and the volume holographic or optical information of the master in a single processing step.

The liquid composition may further comprise at least one aromatic aldehyde and/or aliphatic aldehyde.

Preferably, the aromatic aldehyde is selected from the group consisting of vanillin, coniferylaldehyde, 2-methoxybenzaldehyde, 3-methoxybenzaldehyde, 4-methoxybenzaldehyde, 2-ethoxybenzaldehyde, 3-ethoxybenzaldehyde, 4-ethoxybenzaldehyde, 4-hydroxy-2,3-dimethoxy-benzaldehyde, 4-hydroxy-2,5-dimethoxy-benzaldehyde, 4-hydroxy-2,6-dimethoxy-benzaldehyde, 4-hydroxy-2-methyl-benzaldehyde, 4-hydroxy-3-methyl-benzaldehyde, 4-hydroxy-2,3-dimethyl-benzaldehyde, 4-hydroxy-2,5-dimethyl-benzaldehyde, 4-hydroxy-2,6-dimethyl-benzaldehyde, 4-hydroxy-3,5-dimethoxy-benzaldehyde, 4-hydroxy-3,5-dimethyl-benzaldehyde, 3,5-diethoxy-4-hydroxy-benzaldehyde, 2,6-diethoxy-4-hydroxy-benzaldehyde, 3-hydroxy-4-methoxy-benzaldehyde, 2-hydroxy-4-methoxy-benzaldehyde, 2-ethoxy-4-hydroxy-benzaldehyde, 3-ethoxy-4-hydroxy-benzaldehyde, 4-ethoxy-2-hydroxy-benzaldehyde, 4-ethoxy-3-hydroxy-benzaldehyde, 2,3-dimethoxybenzaldehyde, 2,4-dimethoxybenzaldehyde, 2,5-dimethoxybenzaldehyde, 2,6-dimethoxybenzaldehyde, 3,4-dimethoxybenzaldehyde, 3,5-dimethoxybenzaldehyde, 2,3,4-trimethoxybenzaldehyde, 2,3,5-trimethoxybenzaldehyde, 2,3,6-trimethoxybenzaldehyde, 2,4,6-trimethoxybenzaldehyde, 2,4,5-trimethoxybenzaldehyde, 2,5,6-trimethoxybenzaldehyde, 2-hydroxybenzaldehyde, 3-hydroxybenzaldehyde, 4-hydroxybenzaldehyde, 2,3-dihydroxybenzaldehyde, 2,4-dihydroxybenzaldehyde, 2,4-dihydroxy-3-methylbenzaldehyde, 2,4-dihydroxy-5-methyl-benzaldehyde, 2,4-dihydroxy-6-methyl-benzaldehyde, 2,4-dihydroxy-3-methoxy-benzaldehyde, 2,4-dihydroxy-5-methoxy-benzaldehyde, 2,4-dihydroxy-6-methoxy-benzaldehyde, 2,5-dihydroxybenzaldehyde, 2,6-dihydroxybenzaldehyde, 3,4-dihydroxybenzaldehyde, 3,4-dihydroxy-2-methyl-benzaldehyde, 3,4-dihydroxy-5-methyl-benzaldehyde, 3,4-dihydroxy-6-methyl-benzaldehyde, 3,4-dihydroxy-2-methoxy-benzaldehyde, 3,4-dihydroxy-5-methoxy-benzaldehyde, 3,5-dihydroxybenzaldehyde, 2,3,4-trihydroxybenzaldehyde, 2,3,5-trihydroxybenzaldehyde, 2,3,6-trihydroxybenzaldehyde, 2,4,6-trihydroxybenzaldehyde, 2,4,5-trihydroxybenzaldehyde, 3,4,5-trihydroxybenzaldehyde, 2,5,6-trihydroxybenzaldehyde, 4-hydroxy-2-methoxybenzaldehyde, 4-dimethylaminobenzaldehyde, 4-diethylaminobenzaldehyde, 4-dimethylamino-2-hydroxybenzaldehyde, 4-diethylamino-2-hydroxybenzaldehyde, 4-pyrrolidinobenzaldehyde, 4-morpholinobenzaldehyde, 2-morpholinobenzaldehyde, 4-piperidinobenzaldehyde, 2-methoxy-1-naphthaldehyde, 4-methoxy-1-naphthaldehyde, 2-hydroxy-1-naphthaldehyde, 2,4-dihydroxy-1-naphthaldehyde, 4-hydroxy-3-methoxy-1-naphthaldehyde, 2-hydroxy-4-methoxy-1-naphthaldehyde, 3-hydroxy-4-methoxy-1-naphthaldehyde, 2,4-dimethoxy-1-naphthaldehyde, 3,4-dimethoxy-1-naphthaldehyde, 4-hydroxy-1-naphthaldehyde, 4-dimethylamino-1-naphthaldehyde, 4-dimethylamino-cinnamaldehyde, 2-dimethylaminobenzaldehyde, 2-chloro-4-dimethylaminobenzaldehyde, 4-dimethylamino-2-methylbenzaldehyde, 4-diethylamino-cinnamaldehyde, 4-dibutylamino-benzaldehyde, 4-diphenylamino-benzaldehyde, 4-dimethylamino-2-methoxybenzaldehyde, 4-(1-imidazolyl)-benzaldehyde, piperonal, 2,3,6,7-tetrahydro-1H,5H-benzo[ij]quinolizine-9-carboxaldehyde, 2,3,6,7-tetrahydro-8-hydroxy-1H,5H-benzo[ij]quinolizine-9-carboxaldehyde, N-ethylcarbazole-3-aldehyde, 2-formylmethylene-1,3,3-trimethylindoline (Fischer's aldehyde or tribase aldehyde), 2-indole aldehyde, 3-indole aldehyde, 1-methylindole-3-aldehyde, 2-methylindole-3-aldehyde, 1-acetylindole-3-aldehyde, 3-acetylindole, 1-methyl-3-acetylindole, 2-(1′,3′,3′-trimethyl-2-indolinylidene)-acetaldehyde, 1-methylpyrrole-2-aldehyde, 1-methyl-2-acetylpyrrole, 4-pyridinaldehyde, 2-pyridinaldehyde, 3-pyridinaldehyde, 4-acetylpyridine, 2-acetylpyridine, 3-acetylpyridine, pyridoxal, quinoline-3-aldehyde, quinoline-4-aldehyde, antipyrine-4-aldehyde, furfural, 5-nitrofurfural, 2-thenoyl-trifluoroacetone, chromone-3-aldehyde, 3-(5′-nitro-2′-furyl)-acrolein, 3-(2′-furyl)-acrolein and imidazole-2-aldehyde.

Particularly preferred is the aromatic aldehyde selected from the group consisting of 2,3-dihydroxybenzaldehyde, 2,4-dihydroxybenzaldehyde, 2,4-dihydroxy-3-methyl-benzaldehyde, 2,4-dihydroxy-5-methyl-benzaldehyde, 2,4-dihydroxy-6-methyl-benzaldehyde, 2,4-dihydroxy-3-methoxy-benzaldehyde, 2,4-dihydroxy-5-methoxy-benzaldehyde, 2,4-dihydroxy-6-methoxy-benzaldehyde, 2,5-dihydroxybenzaldehyde, 2,6-dihydroxybenzaldehyde, 3,4-dihydroxybenzaldehyde, 3,4-dihydroxy-2-methyl-benzaldehyde, 3,4-dihydroxy-5-methyl-benzaldehyde, 3,4-dihydroxy-6-methyl-benzaldehyde, 3,4-dihydroxy-2-methoxy-benzaldehyde, 3,4-dihydroxy-5-methoxy-benzaldehyde, 3,5-dihydroxybenzaldehyde.

Very preferably, the aromatic aldehyde is selected from the group consisting of 2,4-dihydroxybenzaldehyde, 2,5-dihydroxybenzaldehyde, 2,6-dihydroxybenzaldehyde and 3,5-dihydroxybenzaldehyde.

Particularly preferred is a kit-of-parts for the preparation of a photopolymerizable composition by UV/Vis irradiation, comprising:
I) a dye concentrate comprising
   A) a first mixture A, in particular liquid mixture A, comprising
      f) at least one dye selected from the group consisting of acriflavins, diaminoacridins, rhodamine B, safranin-O, diethylsafranins and methylene blue.
         and
      h) at least one solvent selected from the group consisting of dimethyl sulphoxide (DMSO), N,N′-dimethylpropylene urea, N-hydroxyethylacrylamide (HEAA), N-methyl-2-pyrrolidone (NMP), benzaldehyde, polyethylene glycols (PEGs), polycaprolactones, acrylate block copoylmers (EFKA) and poly(bisphenol A-co-epichlorohydrins),
         and
II) a liquid composition comprising:
   B) a monomer-containing liquid mixture B comprising:
      a) at least one monomer M1 comprising at least one ethylenically un-saturated group,
      c) at least one co-photoinitiator selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

Particularly preferred is a kit-of-parts for the preparation of a photopolymerizable composition by UV/Vis irradiation, comprising:
I) a dye concentrate comprising
   A) a first mixture A, in particular liquid mixture A, comprising
      f) at least one dye selected from the group consisting of acriflavins, diaminoacridins, rhodamine B, safranin-O, diethylsafranins and methylene blue,
      (g) at least one photoinitiator; and
      (h) at least one solvent
         and
II) a liquid composition comprising:
   B) a monomer-containing liquid mixture B comprising:
      a) at least one monomer M1 comprising at least one ethylenically un-saturated group,
      c) at least one co-photoinitiator selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

Preferably, the kit-of-parts comprises at most 10% by weight of a first mixture A, based on the total amount of mixture B.

Very particularly preferred is a kit-of-parts for the preparation of a photopolymerizable composition by UV/Vis irradiation, comprising:
I) 0.1 to 5% by weight of a dye concentrate comprising
   A) a first mixture A comprising
      f) at least one dye selected from the group consisting of acriflavins, diaminoacridins, rhodamine B, safranin-O, diethylsafranins and methylene blue,
      (g) at least one photoinitiator; and
      (h) at least one solvent
         and
II) from 95 to 99.9% by weight of a liquid composition comprising:
   B) a monomer-containing liquid mixture B comprising:
      a) at least one monomer M1 comprising at least one ethylenically unsaturated group,
      c) at least one co-photoinitiator selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof, wherein the total of I) and II) equals 100% by weight.

Preferably, the kit-of-parts comprises at most 10% by weight of a first mixture A, based on the total amount of mixture B.

Very particularly preferred is a kit-of-parts for the preparation of a photopolymerizable composition by UV/Vis irradiation, comprising:
I) 0.1 to 5% by weight of a dye concentrate comprising
   A) a first mixture A comprising
      f) 0.5 to 5% by weight of at least one dye selected from the group consisting of acriflavins, diaminoacridins, rhodamine B, safranin-O, diethylsafranins and methylene blue,
      (g) 9,5 to 99,5% by weight of at least one photoinitiator; and
      h) 0 to 90% by weight of at least one solvent, the total amount of f) to h) being 100% by weight
         and
II) from 95 to 99.9% by weight of a liquid composition comprising:
   B) a monomer-containing liquid mixture B comprising:
      a) from 49.9 to 99.9% by weight of at least one monomer M1 comprising at least one ethylenically unsaturated group,
      c) 0.1 to 10% by weight of at least one co-photoinitiator selected from the group consisting of tetrabutylammonium tetrahexylborate, tetrabutylammonium triphenylhexylborate, tetrabutylammonium tris-(3-fluoro-phenyl)-hexylborate and tetrabutylammonium tris-(3-chloro-4-methylphenyl)-hexylborate or mixtures thereof, the total amount of a) and c) being at least 50% and not more than 100% by weight.
         and where the total of I) and II) is 100% by weight.

Another object of the invention is an element comprising a component obtainable by exposing the photopolymerizable composition prepared from the kit-of-parts of the invention to (actinic) UV/VIS radiation.

Preferably, an element comprising a hologram obtainable by exposing the photopolymerizable composition of the kit-of-parts of the invention to modulated radiation carrying holographic information. For this purpose, the photopolymerizable composition from the kit-of-parts can advantageously be applied to a substrate, for example a mirror sheet, a surface mirror, a nickel shim with holographic or optical surface structures or to a master hologram, and exposed to a laser beam so that a hologram is formed. Advantageously, the photopolymerizable composition from the kit-of-parts is then cured with UV light.

Another object of the invention is the use of the element according to the invention as a film, lens, grating, prism, mirror, beam splitter, diffuser, surface relief, membrane, filter or sensor.

Preferred is the use of the element according to the invention for a head-up display, data glasses, light guiding system, spectrometer, detection system, security element or label.

Advantageously, the dye concentrate does not attack or alter previously exposed hologram layers.

### Advantages of the Kit-of-Parts

Immediately exposable after mixing
No waiting times and changes in material properties over time due to evaporation and changes in solvent concentration
No vapours that are harmful to health and the environment
No explosion protection necessary
Good compatibility, no deterioration of the hologram properties
previously exposed hologram layers are not attacked or changed
the separate storage of dye concentrate and hologram material improves shelf life and simplifies storage. The material is thus less sensitive to light and heat
The photopolymerizable compositions that can be produced from the Kit of Parts can be individually adapted to the type of exposure and the desired results depending on the application. By selecting the appropriate dye concentrate and varying the quantity, the optimum color intensity can be set depending on the layer thickness, the desired sensitivity and the tolerable color shade in the finished product.
the substances used do not deteriorate or even improve the holographic properties of the photopolymerizable composition
the quality of the kit-of-parts can be assessed in normal ambient light
due to the short time span between mixing, application and exposure, the demands on the color and brightness of the ambient light are low.

### EXAMPLES

List of abbreviations

| | |
|---|---|
| BWG, η | Diffraction efficiency (“Beugungswirkungsgrad”) |
| CN 9002 | Aliphatic urethane acrylate |
| DMSO | Dimethyl sulphoxide |
| Ebecryl 230 | Aliphatic urethane diacrylate |
| EFKA | Acrylic block copolymer |
| EPI | Poly(bisphenol A-co-epichloro-hydrin) glycidyl end- |
| | capped |
| Hedipine R/2000 | Ethoxylated castor oil |
| HEAA | N-hydroxyethylacrylamide |
| Irgacure OXE01 | Oxime ester radical initiator [1-(4-phenyl- |
| | sulfanylbenzoyl)heptylideneamino]benzoate |
| NPG | N-phenylglycine |
| Omnirad 1173 | 2-Hydroxy-2-methyl-1-phenylpropanone |
| PCL-triol | Poly-(caprolactone)-triol, Mₙ~300 |
| PEG-200 | Polyethylene glycol, Mₙ~200 |
| PEG-PP-PEG | Poly(ethylene glycol)-block-poly(propylene glycol)- |
| | block-poly(ethylene glycol |
| PolyCLO | Capromer PT-05, polycaprolactone, Mₙ~540 |
| SEC LCA 1460 | Borate salt, co-initiator |
| SR 349 | Ethoxylated bisphenol A diacrylate |
| T_{Peak} | Peak value, transmission at the wavelength that fulfils |
| | the Bragg condition |
| T_{Ref} | Reference value, transmission without hologram |

### Dyes

Molecular structures with a main framework of three benzene rings proved to be particularly suitable dyes.

### Examples

| Exposure with | Dye | Molecule | CAS |
|---|---|---|---|
| green | Safranin-O | 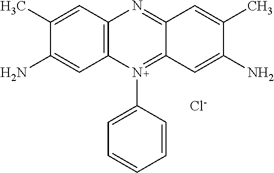 | 477-73-6 |
| yellow | Diethyl- safranin | 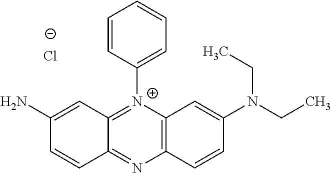 [SMILES: CCN(CC)c1ccc2nc3ccc(N)cc3[n+](-c3ccccc3)c2c1 ; [Cl-]] | 4569-86-3 |
| yellow | Rhodamine- B | 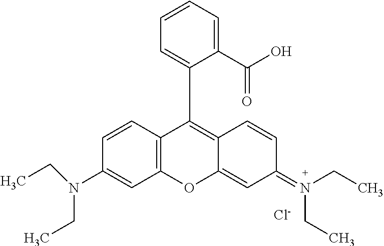 | 81-88-9 |
| red | Methylene blue | 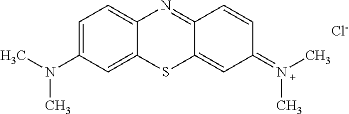 | 61-73-4 |
| blue | Acriflavine | 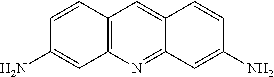 [SMILES: Nc1ccc2cc3ccc(N)cc3nc2c1] | 8048-52-0 |
| | | 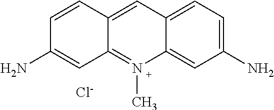 | |
| blue | Acriflavine hydro- chloride | 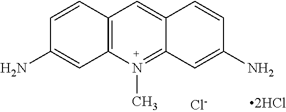 | 8063-24-9 |
| | | 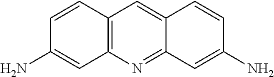 [SMILES: Nc1ccc2cc3ccc(N)cc3nc2c1] | |
| blue | 3,6-Diamino- acridine hydrichloride | 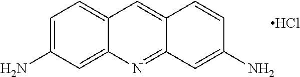 [SMILES: Nc1ccc2cc3ccc(N)cc3nc2c1 ; Cl] | 962-23-8 |

### UV Initiators

### Liquid UV Initiators

The dyes are in powder form. In order to add them to the mixture, they have to be dissolved. It turned out that they dissolve well in liquid UV photoinitiators. This is advantageous because after laser exposure UV initiators are needed anyway for the final UV curing.

### Examples

| Brand name | CAS | Molecule |
|---|---|---|
| Omnirad MBF (IGM) | 15206-55-0 | 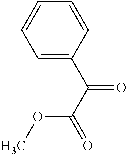 |
| Omnirad 1173 or also Called Omnirad 73 (IGM) | 7473-98-5 | 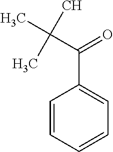 |
| Omnirad 1000 (IGM) | 7473-98-5 + 947-19-3 | 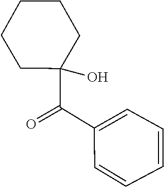 [SMILES: Cc1ccc(C(=O)C2(O)CCCCC2)cc1] |
| | | 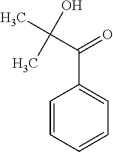 |
| Omnirad TPO-L (IGM) | 84434-11-7 | 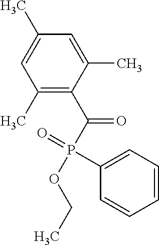 [SMILES: CCOP(=O)(C(=O)c1c(C)cc(C)cc1C)c1ccccc1] |

### Powder UV Initiators

UV initiators in powder form at room temperature can also be used if they are melted or dissolved in a second component.

### Examples

| Brand name | CAS | Molecule |
|---|---|---|
| Omnirad 184 (IGM) | 947-19-3 | 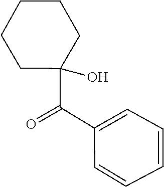 [SMILES: Cc1ccc(C(=O)C2(O)CCCCC2)cc1] |
| Omnirad 819 (IGM) | 162881-26-7 | 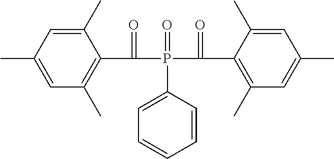 |
| Omnirad TPO (IGM) | 75980-60-8 | 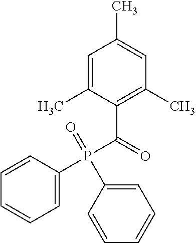 [SMILES: Cc1cc(C)c(C(=O)P(=O)(c2ccccc2)c2ccccc2)c(C)c1] |
| OXE-01 (BASF) | 253585-83-0 | 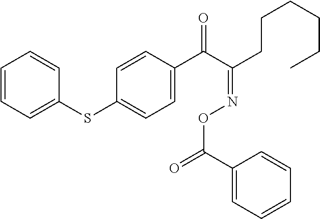 [SMILES: CCCCCC/C(=N/OC(=O)c1ccccc1)C(=O)c1ccc(Sc2ccccc2)cc1] |

### Solvents

### Volatile

### Examples

| Designation | Molecule | CAS | Molar mass | Vapour pressure | Boiling point |
|---|---|---|---|---|---|
| Ethanol | 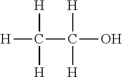 | 37625-56-2 | 46 g/mol | 58 hPa at 20° C. | 78° C. |

### High-boiling

### Examples

| Designation | Molecule | CAS | Molar mass | Vapour pressure | Boiling point |
|---|---|---|---|---|---|
| Dimethyl sulphoxide, DMSO | 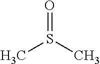 | 67-68-5 | 78 g/mol | 0.42 hPa at 20° C. | 189° C. |
| N,N′-dimethyl- propylene urea | 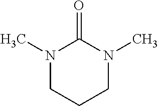 | 7226-23-5 | 128 g/mol | 0.02 hPa at 20° C. | 247° C. |
| N-methyl-2- pyrrolidone (NMP) | 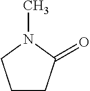 | 872-50-4 | 99 g/mol | 0.32 hPa at 20° C. | 204° C. |
| Benzalde- hyde | 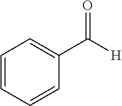 | 100-52-7 | 106 g/mol | 1.26 hPa at 20° C. | 179° C. |
| N-Hydroxy- ethylacryl- amide (HEAA) | 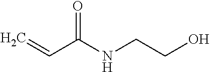 | 7646-67-5 | 115 g/mol | | 130° C. |

### High Molecular Weight

### Examples

| Designation | Molecule | CAS | Molar mass |
|---|---|---|---|
| PolyCLO TMP540, Poly- caprolactone, Capromer PT1-05 (BASF) | 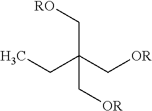 | 37625-56-2 | 540 g/mol |
| | 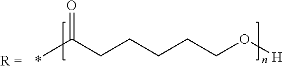 | | |
| Polycapro- lactone triol, PCL- triol (Sigma- Aldrich) | 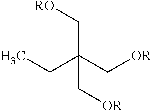 | 37625-56-2 | 300 g/mol |
| | 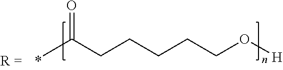 | | |
| Poly (BISPHENOL- A- CO- EPICHLORO- HyDRIN) | 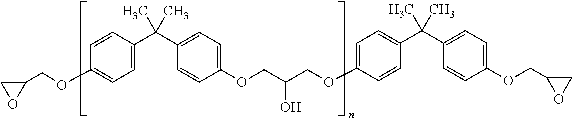 | 25036-25-3 | 377 g/mol |
| Polyethylene glycol, PEG 200 | 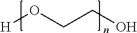 | 25322-68-3 | 200 g/mol |
| Efka ® PX | acrylic block copolymer | | |
| 4701 | | | |
| (BASF) | | | |

### Dye Concentrates

Preferably, a mixture of polycaprolactone and a liquid UV photoinitiator (e.g. Omnicure 1173 or MBF) is used to dissolve the dyes. Instead of a liquid UV photoinitiator, a UV-Initiatior that is solid at room temperature such as Omnicure TPO, Omnicure 819 and Omnicure 189 can also be dissolved in the low molecular polycaprolactone. The ratio is chosen so that the UV initiator and the dye are later present at the desired concentration in the photopolymerizable composition from the kit-of-parts.

### Example

| | |
|---|---|
| Quantity | Ingredient |

| | | |
|---|---|---|
| 2 | g | PCL-triol (Polycaprolactone triol), Mn 300 g/mol |
| 1 | g | Omnirad 1173 |
| 0.1 | g | Diethylsafranin |

If this amount of 3.1 g in total is added to 96.9 g of a monomer-containing liquid mixture, then the UV initiator concentration in the resulting photopolymerizable composition from the kit-of-parts is 1%. If a different concentration were desired, then the ratio of PCL-triol and UV initiator would have to be adjusted accordingly. In this example, a maximum photoinitiator concentration of 3% would be possible.

### Other Ingredients

Depending on the dye and UV initiator used, it may be useful to add further co-initiators such as N-phenylglycine(NPG), an amine synergist such as PHOTOCRYL A101 from Miwon or a monomer such as N-hydroxyethylacrylamide.

Dye Concentrates FK1 to FK5 (Kit-of-parts I)

The dye concentrates FK1 to FK5 were prepared analogously to dye concentrate 1. The components are added one after the other into a beaker with a stirring magnet. The beaker is placed on a scale for this purpose so that the liquid substances can be added in the correct quantity. Then everything is heated to 120° C. on a heatable stirring table and stirred. The powdery substances are dosed with the help of weighing trays and added to the mixture while stirring. The mixture is stirred at 120° C. for about 1 h before the solution is filtered and filled into a bottle.

### Dye Concentrates FK1

| Quantity [g] | Quantity [%] | Designation |
|---|---|---|
| 19.55 | 65.17% | PolyCLO TMP540 |
| 10.00 | 33.33% | Omnirad 1173 |
| 0.15 | 0.50% | NPG |
| 0.30 | 1.00% | Methylene blue |
| 30.00 | 100.00% | |

### Dye Concentrates FK2

| Quantity [g] | Quantity [%] | Designation |
|---|---|---|
| 8.10 | 27.00% | PolyCLO TMP540 |
| 20.00 | 66.67% | Omnirad 1173 |
| 1.00 | 3.33% | DMSO |
| 0.30 | 1.00% | NPG |
| 0.60 | 2.00% | Methylene blue |
| 30.00 | 100.00% | |

### Dye Concentrates FK3

| Quantity [g] | Quantity [%] | Designation |
|---|---|---|
| 0.97 | 4.85% | EFKA PX 4701 |
| 1.94 | 9.70% | N-hydroxyethylacrylamide |
| 16.45 | 82.25% | PEG-200 |
| 0.64 | 3.20% | Methylene blue |
| 20.00 | 100.00% | |

### Dye Concentrates FK4

| Quantity [g] | Quantity [%] | Designation |
|---|---|---|
| 4.80 | 96.00% | Ethanol |
| 0.20 | 4.00% | Methylene blue |
| 5.00 | 100.00% | |

### Dye Concentrates FK5

| Quantity | Quantity | |
|---|---|---|
| [g] | [%] | Designation |
| 12.00 | 40.00% | PCL-triol (Polycaprolactone triol), 300 g/mol |
| 12.00 | 40.00% | Omnirad 1173 |
| 5.40 | 18.00% | Benzaldehyde |
| 0.60 | 2.00% | Methylene blue |
| 30.00 | 100.00% | |

### Liquid Composition (Kit-of-Parts II)

The liquid compositions MM1 to MM4 were prepared using the same procedure as described for the dye concentrates.

### Liquid Composition MM1

| Quantity [g] | Quantity [%] | Designation |
|---|---|---|
| 35 | 79.46% | SR 349 |
| 7 | 15.89% | Castor oil |
| 0.2 | 0.45% | SEC LCA 1460 |
| 0.4 | 0.91% | Irgacure OXE01 |
| 0.25 | 0.57% | 2,4 Dihydroxybenzaldehyde |
| 1.2 | 2.72% | Hedipine R/2000 |
| 44.05 | 100.00% | |

### Liquid Composition MM2

| Quantity [g] | Quantity [%] | Designation |
|---|---|---|
| 31.78 | 63.56% | SR 349 |
| 6.36 | 12.72% | Castor oil |
| 0.18 | 0.36% | SEC LCA 1460 |
| 0.36 | 0.72% | Irgacure OXE01 |
| 0.23 | 0.46% | 2,4 Dihydroxybenzaldehyde |
| 1.09 | 2.18% | Hedipine R/2000 |
| 7.00 | 14.00% | EPI |
| 3.00 | 6.00% | PEG-PP-PEG |
| 50.00 | 100.00% | |

### Liquid Composition MM3

| Quantity [g] | Quantity [%] | Designation |
|---|---|---|
| 287.5 | 57.16% | SR 349 |
| 212.5 | 42.25% | Ebecryl 230 |
| 3 | 0.60% | SEC LCA 1460 |
| 503.00 | 100.00% | |

### Liquid Composition MM4

| Quantity [g] | Quantity [%] | Designation |
|---|---|---|
| 23 | 57.07% | SR 349 |
| 17 | 42.185% | CN 9002 |
| 0.3 | 0.74% | SEC LCA 1460 |
| 40.30 | 100.00% | |

### Kit-of-Parts

A photopolymerizable composition is formed from the previously described dye concentrates and the monomer-containing liquid compositions, which together form a corresponding kit-of-parts, by mixing (for example by shaking with a speed mixer or stirring with a stirring rod). The following photopolymerizable compositions are described:

### Photopolymerizable Composition A

| Quantity [g] | Quantity [%] | Component | Name |
|---|---|---|---|
| 5 | 97.09% | MM2 | Liquid composition |
| 0.15 | 1.91% | FK1 | Dye concentrate |
| 5.15 | 100.00% | | |

### Photopolymerizable Composition B

| Quantity [g] | Quantity [%] | Component | Name |
|---|---|---|---|
| 5 | 97.09% | MM3 | Liquid composition |
| 0.15 | 1.91% | FK1 | Dye concentrate |
| 5.15 | 100.00% | | |

### Photopolymerizable Composition C

| Quantity [g] | Quantity [%] | Component | Name |
|---|---|---|---|
| 5 | 98.62% | MM2 | Liquid composition |
| 0.07 | 1.38% | FK2 | Dye concentrate |
| 5.07 | 100.00% | | |

### Photopolvmerizable Composition D

| Quantity [g] | Quantity [%] | Component | Name |
|---|---|---|---|
| 5 | 98.62% | MM3 | Liquid composition |
| 0.07 | 1.38% | FK2 | Dye concentrate |
| 5.07 | 100.00% | | |

### Photopolymerizable Composition E

| Quantity [g] | Quantity [%] | Component | Name |
|---|---|---|---|
| 5 | 97.09% | MM2 | Liquid composition |
| 0.15 | 2.91% | FK3 | Dye concentrate |
| 5.15 | 100.00% | | |

### Photopolymerizable Composition F

| Quantity [g] | Quantity [%] | Component | Name |
|---|---|---|---|
| 5 | 97.09% | MM2 | Liquid composition |
| 0.15 | 2.91% | FK4 | Dye concentrate |
| 5.15 | 100.00% | | |

### Photopolymerizable Composition G

| Quantity [g] | Quantity [%] | Component | Name |
|---|---|---|---|
| 5 | 97.09% | MM1 | Liquid composition |
| 0.15 | 2.91% | FK1 | Dye concentrate |
| 5.15 | 100.00% | | |

### Photopolymerizable Composition H

| Quantity [g] | Quantity [%] | Component | Name |
|---|---|---|---|
| 5 | 97.09% | MM4 | Liquid composition |
| 0.15 | 2.91% | FK5 | Dye concentrate |
| 5.15 | 100.00% | | |

### Exposures

### Exposures

| | | | Thick- | no longer | |
|---|---|---|---|---|---|
| Material | Peak[nm] | BWG[%] | ness[μm] | exposable after | |
| A | 585 | 87% | 65 | 0 h | 45 m |
| B | 578 | 87% | 138 | 1 h | 30 m |
| C | 586 | 85% | 69 | 0 h | 40 m |
| D | 577 | 96% | 126 | 1 h | 40 m |
| E | 581 | 95% | 18 | 0 h | 45 m |
| F | 578 | 90% | 24 | 1 h | 8 m |
| G | 577 | 92% | 21 | 2 h | 18 m |
| H | 578 | 96% | 115 | 4 h | 45 m |

* Reference example

Exposure was at a wavelength of 577 nm at a temperature of 20° C. The material was kept in an oven at 120° C. An exposure was made approx. every 15 min until no more holograms could be exposed and the BWG value (Diffraction efficiency) was 0%. The values given are from the first exposure.

The monomer-containing mixtures or the liquid composition of kit-of-parts II were stored at room temperature for at least 3 months. Before use, they were kept in the oven at 120° C. for 4 hours to bring the crystallised borate salts back into solution. Mixture MM2 came from a particularly old batch. It was over 5 years old and was frequently reheated to 120° C. in between without losing quality. The dye concentrate FK3 was also particularly old, being more than three years old. As long as the dye concentrates are stored protected from light, they can be stored at room temperature for at least 1 year as kit-of-parts, just like the monomer-containing liquid compositions.

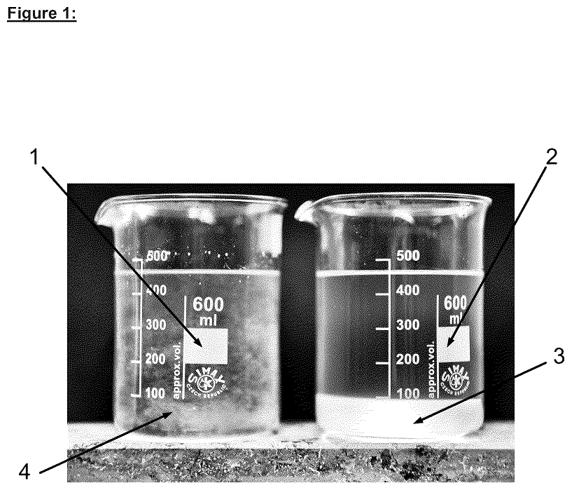

FIG. 1 shows a photo of two mixtures of liquid composition II). The left beaker (1) contains a liquid composition II) that has been stored at room temperature for a longer period of time, more than three months. In the right beaker (2) there is a liquid composition II) which was stirred shortly before at 120° C. for three hours on a hot plate with a magnetic stirrer (3). It can be clearly seen that this mixture (2) is clearer than the untreated stored one (1) with the crystallisations (4).

### Exposure Setup

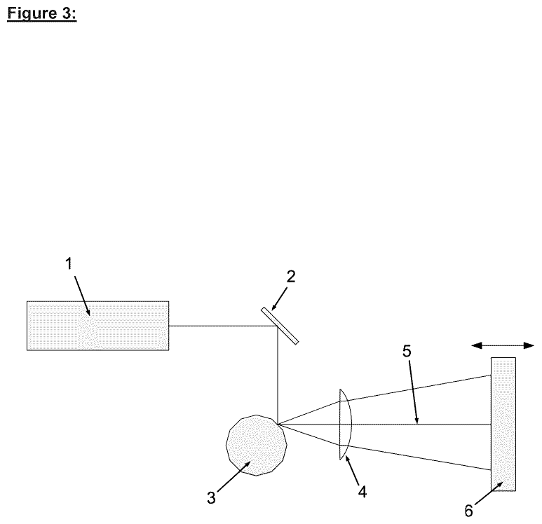

The laser beam with a measured power of 1.43W was expanded horizontally with a polygon scanner and focused by a cylindrical lens so that it covered an exposure width of 23 cm. FIG. 3 shows the schematic exposure setup.

### Reference Sign in FIG. 3

1 Laser 577 nm
2 Mirror
3 Polygon scanner
4 Cylinder lens
5 Scanning beam
6 Scanner mirror

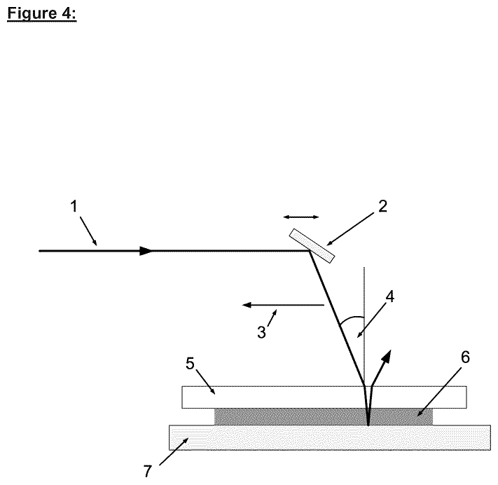

The respective samples were scanned with this line using a movable mirror and exposed. The traversing speed was set to 9 mm/s. The laser beam fell on the sample surface at an angle of 22° to the perpendicular. FIG. 4 shows the beam path.

### Reference Signs in FIG. 4

1 Scanning beam 577 nm
2 Scanner mirror
3 Exposure direction
4 Exposure angle, 22°
5 Substrate, glass or film
6 Photopolymer (photopolymerizable composition)
7 Master, mirror sheet

To create a reflection hologram, the sample material was applied to a mirror sheet which reflects the laser light back. The interference of the incident beam with the reflected beam creates a line pattern of light and dark spots parallel to the surface of the mirror. This interference pattern is recorded by the material in the form of a refractive index modulation and a so-called Lippmann-Bragg hologram is created.

With laser exposure, the photopolymer layer is located between the mirror sheet and a transparent substrate, e.g. a PET film or glass.

After laser exposure, the material is still cured with UV light. For the first curing step we use a UV flash with a power of 3000 WS. This is sufficient to remove the hologram with the carrier from the sheet. To ensure adhesion to the glass, it should be pre-treated with a primer.

Optionally, the hologram layer can then be further cured and bleached under a standard UV lamp with a mercury vapour bulb. We use a UV bridge with an arc length of 70 mm and a power of 120 W/cm for this. Samples B, D, and H were irradiated with this for 30 s, while the other samples remained untreated and were measured after flashing.

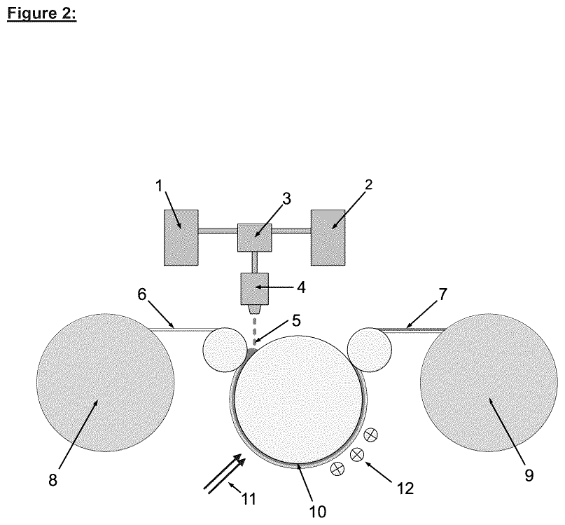

FIG. 2 shows a device for producing the hologram made from the claimed kit-of-parts.

### Measurement Setup

The samples were measured with a spectrometer (CAS 140 B from Instrument Systems) in transmitted light. This was done with perpendicular illumination. Since the hologram only reflects the wavelength that fulfils the Bragg condition, a clear absorption peak can be seen in the spectral curve at this point.

From the peak value T_{Peak} and a nearby reference value T_{Ref} on the upper baseline, the diffraction efficiency (BWG) η is calculated as follows:

η=(T_{Ref}−T_{Peak})/T_{Ref}

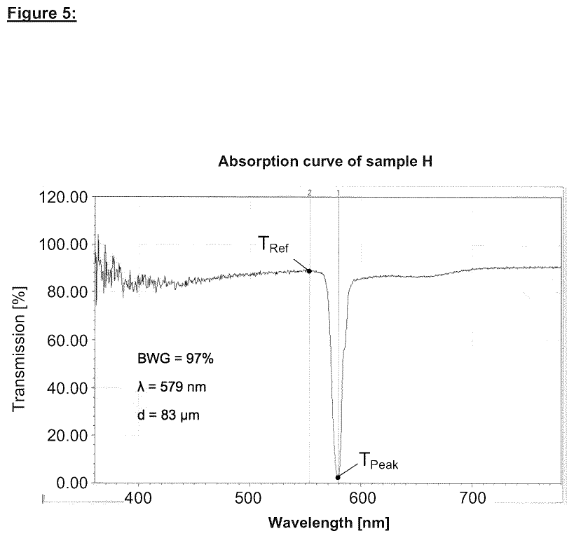

FIG. 5 shows the measurement curve with the corresponding measurement points of the first exposure of sample H.

The table values of the exposures show that all sample mixtures achieve a high diffraction efficiency at the first exposure. But the longer the exposable material is kept at a high temperature, the worse the results become until after a certain time no holograms can be inscribed at all.

### Manufacturing

FIG. 2 shows the schematic construction of a compact roll-to-roll machine for the production of sealed holographic contact copies from the claimed kit-of-parts.

### Reference Signs in FIG. 2

1 Storage container for component A
2 Storage container for component B
3 Mixer
4 Dosing unit
5 Photopolymer (photopolymerizable composition)
6 Support film
7 Support film with hologram
8 Film unwinder
9 Film winder
10 Master
11 Laser light
12 UV light

1-15. (canceled)

16. A kit-of-parts for the preparation of a photopolymerizable composition by means of UV/Vis irradiation, comprising:
I) a dye concentrate comprising
A) a first mixture A comprising:
(f) at least one dye; and
(h) at least one solvent,
and
II) a liquid composition comprising:
B) a monomer-containing liquid mixture B comprising:
a) at least one monomer M1 comprising at least one ethylenically unsaturated group,
c) at least one co-photoinitiator,
wherein more than 80% of all components of the solvent in the kit-of-parts or in the dye concentrate have a vapor pressure of≤2 hPa at 20° C. and a boiling point of≥100° C. at standard pressure, and
wherein a polymer which is liquid under standard pressure is contained in the solvent and wherein, after mixing of the photopolymerizable composition, it is immediately processable and exposable.

17. The kit-of-parts according to claim 16, wherein the first mixture A further comprises:
(g) at least one photoinitiator,
wherein the photoinitiator can form radicals under irradiation with a wavelength between 100 nm and 480 nm.

18. The kit-of-parts according to claim 17, wherein the photoinitiator is liquid and/or selected from the group consisting of 1,2-octanedione-1-[4-(phenylthio)-phenyl]-2-(O-benzoyloxime), (1-[9-ethyl-6-(2-methylbenzoyl)-9H-carbazol-3-yl]ethanone-O-acetyloxime, methylbenzoyl formate), 2,4,6-trimethylbenzoyl diphenyl phosphine oxide, ethyl (2,4,6-trimethylbenzoyl) phenyl phosphinate), 2-hydroxy-2-methyl-1-phenyl propanone, a mixture of 2-hydroxy-2-methyl-1-phenylpropanone (80%) and 1-hydroxycyclohexyl-phenylketone (20%), 1-hydroxycyclohexyl-phenylketone, bis(2,4,6-trimethylbenzoyl)phenylphosphine oxide, a mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate), and 4,4′-dimethyl-diphenyl-iodonium hexafluorophosphate.

19. The kit-of-parts according to claim 16, wherein the dye is a fluorescent dye.

20. The kit-of-parts according to claim 16, wherein the dye is selected from the group consisting of acriflavins, diaminoacridins, rhodamine B, safranin-O, diethylsafranin and methylene blue.

21. The kit-of-parts according to claim 16, wherein the co-photoinitiator is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

22. The kit-of-parts according to claim 16, wherein the monomer-containing liquid mixture B is liquid at a standard pressure in the range from 15° C. to 120° C.

23. The kit-of-parts according to claim 16, wherein the polymer liquid under standard pressure is selected from the group consisting of polyethylene glycols (PEGs), polycaprolactones, acrylate block copolymers (EFKA) and poly(bisphenol A-co-epichlorohydrins) (EPI).

24. The kit-of-parts according to claim 16, comprising:
I) not more than 10% by weight of a first mixture A, based on the total amount of mixture B.

25. An element comprising a component obtainable by the action of UV/VIS radiation on the photopolymerizable composition from the kit-of-parts according to claim 16.

26. The element according to claim 25, comprising a hologram obtainable by exposing the photopolymerizable composition to modulated radiation carrying holographic information.

27. A film, lens, grating, prism, mirror, beam splitter, diffuser, surface relief, membrane, filter or sensor comprising the element of claim 25.

28. A head-up display, data glasses, light guidance system, spectrometer, detection system, security element or label comprising the element of claim 25.

29. The element of claim 25, wherein UV/VIS radiation is actinic UV/VIS radiation.
